(19) United States
(12) Patent Application Publication
(10) Pub. No.: US 2011/0101333 A1
(43) Pub. Date: May 5, 2011

(54) SEMICONDUCTOR DEVICE

(75) Inventors: Yutaka SHIONOIRI, Isehara (JP); Kosei NODA, Atsugi (JP)

(73) Assignee: SEMICONDUCTOR ENERGY LABORATORY CO., LTD., Atsugi (JP)

(21) Appl. No.: 12/912,083

(22) Filed: Oct. 26, 2010

(30) Foreign Application Priority Data
Oct. 30, 2009 (JP) 2009-250665

(51) Int. Cl. H01L 29/12

(52) U.S. Cl. 257/43; 257/E29.068

(57) ABSTRACT

An object is to provide a semiconductor device with reduced standby power. A transistor including an oxide semiconductor as an active layer is used as a switching element, and supply of a power supply voltage to a circuit in an integrated circuit is controlled by the switching element. Specifically, when the circuit is in an operation state, supply of the power supply voltage to the circuit is performed by the switching element, and when the circuit is in a stop state, supply of the power supply voltage to the circuit is stopped by the switching element. In addition, the circuit supplied with the power supply voltage includes a semiconductor element which is a minimum unit included in an integrated circuit formed using a semiconductor. Further, the semiconductor included in the semiconductor element contains silicon having crystallinity (crystalline silicon).

### TECHNICAL FIELD

The present invention relates to a semiconductor device including a thin semiconductor film.

### BACKGROUND ART

A thin film transistor including a semiconductor film which is formed over an insulating surface is an indispensable semiconductor element for a semiconductor device. Since there is limitation on the allowable temperature limit of a substrate in manufacture of a thin film transistor, a thin film transistor in which amorphous silicon that can be deposited at relatively low temperature, polysilicon that can be obtained by crystallization with use of laser beam or a catalytic element, or the like is included in an active layer is mainly used for a semiconductor display device.

In recent years, a metal oxide showing semiconductor characteristics has attracted attention, which is called an oxide semiconductor, as a novel semiconductor material which has higher mobility than amorphous silicon and has uniform element characteristics obtained by amorphous silicon. The metal oxide is used for various applications. For example, indium oxide is a well-known metal oxide and used as a material of a transparent electrode included in a liquid crystal display device or the like. Examples of such metal oxides having semiconductor characteristics include tungsten oxide, tin oxide, indium oxide, and zinc oxide. Thin film transistors in each of which a channel formation region is formed using such metal oxide having semiconductor characteristics have been known (Patent Documents 1 and 2).

### [Reference]

### [Patent Documents]

[Patent Document 1] Japanese Published Patent Application No. 2007-123861
[Patent Document 2] Japanese Published Patent Application No. 2007-096055

Meanwhile, power consumption of a semiconductor integrated circuit (hereinafter, referred to as an integrated circuit) which is manufactured using a silicon wafer, an SOI (silicon on insulator) substrate, or a thin semiconductor film over an insulating surface, or the like is approximately equal to the sum of power consumption generated when the circuit is in an operation state and power consumption generated when the circuit is in a stop state (hereinafter, referred to as standby power). As the integration degree of the integrated circuit is increased in accordance with advance in micro fabrication, driving voltage is reduced; therefore, the power consumption generated when the circuit is in an operation state tends to be reduced. Accordingly, the proportion of standby power in the total power consumption has been increased, and therefore, reduction of standby power is an important object in order to further reduce power consumption.

The standby power can be classified into static standby power and dynamic standby power. The static standby power is power consumed by generation of leakage current between a source electrode and a drain electrode, between a gate electrode and the source electrode, and between the gate electrode and the drain electrode in a state where voltage is not applied between the electrodes of a transistor, which is an element having three terminals, that is, in a state where voltage between the gate electrode and the source electrode is approximately 0. In addition, the dynamic standby power is power which is consumed when parasitic capacitance included in a gate capacitor, a wiring, or the like of a transistor is charged and discharged by continually supplying voltage of various signals such as clock signals or a power supply voltage to a circuit in a stop state (hereinafter, referred to as a non-operation circuit).

When the integrated degree is increased, the channel length of a transistor is shortened and the thickness of any of insulating films typified by a gate insulating film is reduced. Therefore, the leakage current of the transistor is increased and the static standby power tends to be increased.

In addition, in order to reduce the dynamic standby power, it is effective to prevent unnecessary charge and discharge in a variety of capacitors included in the non-operation circuit by stopping supply of the power supply voltage to the non-operation circuit. However, in general, a transistor is also used as a switching element for stopping supply of the power supply voltage. Further, as described above, with a higher integrated degree, the leakage current of the transistor tends to be increased. As a result, reduction of the dynamic standby power is inhibited by the leakage current.

In view of the above problems, an object of an embodiment of the present invention disclosed is to provide a semiconductor device in which standby power is reduced, and to provide a method for manufacturing the semiconductor device.

A transistor including an oxide semiconductor as an active layer is used as a switching element, and supply of a power supply voltage to a circuit included in an integrated circuit is controlled by the switching element. Specifically, when the circuit is in an operation state, supply of the power supply voltage to the circuit is performed by the switching element, and when the circuit is in a stop state, supply of the power supply voltage to the circuit is stopped by the switching element. In addition, the circuit supplied with the power supply voltage includes one or a plurality of semiconductor elements each of which is a minimum unit included in an integrated circuit, such as a transistor, a diode, a capacitor, a resistor, or inductance, which is formed using a semiconductor. Further, the semiconductor included in the semiconductor elements contains silicon having crystallinity (crystalline silicon), such as microcrystalline silicon, polycrystalline silicon, or single crystal silicon.

In addition, impurities such as moisture or hydrogen which exist in an oxide semiconductor film, in a gate insulating film, in an interface between the oxide semiconductor film and another insulating film or the vicinity thereof are detached by heat treatment or the like.

An oxide semiconductor highly-purified by reduction of impurities such as moisture or hydrogen which serves as an electron donor (donor) (a purified OS) is an intrinsic semiconductor (an i-type semiconductor) or a substantially intrinsic semiconductor. Therefore, a transistor including the oxide semiconductor has a characteristic of very small off current. Specifically, the concentration of hydrogen in the highly-purified oxide semiconductor which is measured by secondary ion mass spectrometry (SIMS) is less than or equal to 5×10¹⁹/cm³, preferably less than or equal to 5×10¹⁸/cm³, more preferably less than or equal to 5×10′⁷/cm³, still more preferably less than or equal to 1×10¹⁶/cm³. In addition, the carrier density of the oxide semiconductor film which is measured by Hall effect measurement is less than 1×10¹⁴/cm³, preferably less than 1×10¹²/cm³, more preferably less than 1×10¹¹/cm³. Furthermore, the band gap of the oxide semiconductor is greater than or equal to 2 eV, preferably greater than or equal to 2.5 eV, more preferably greater than or equal to 3 eV. With the use of the oxide semiconductor film which is highly purified by sufficiently reducing the concentration of impurities such as moisture or hydrogen, off current of the transistor can be reduced.

Various experiments can actually prove low off current of the transistor including the highly-purified oxide semiconductor film as an active layer. For example, even with an element with a channel width of 1×10⁶ μm and a channel length of 10 μm, in a range of from 1 V to 10 V of voltage (drain voltage) between a source electrode and a drain electrode, it is possible that off current (which is drain current in the case where voltage between a gate electrode and the source electrode is 0 V or less) is less than or equal to the measurement limit of a semiconductor parameter analyzer, that is, less than or equal to 1×10⁻¹³ A. In this case, it can be found that an off current density corresponding to a value obtained by dividing the off current by the channel width of the transistor is less than or equal to 100 zA/μm. In addition, a capacitor and a transistor were connected to each other and an off current density was measured by using a circuit in which electric charge flowing into or from the capacitor was controlled by the transistor. In the measurement, the highly-purified oxide semiconductor film was used as a channel formation region in the transistor, and the off current density of the transistor was measured from change in the amount of electric charge of the capacitor per unit time. As a result, it was found that in the case where the voltage between the source electrode and the drain electrode of the transistor was 3V, a lower off current density of several tens yoctoampere per micrometer (yA//μm) was able to be obtained. Therefore, in the semiconductor device relating to an embodiment of the present invention, the off current density of the transistor including the highly-purified oxide semiconductor film as an active layer can be less than or equal to 100 yA/μm, preferably less than or equal to 10 yA/μm, or more preferably less than or equal to 1 yA/μm, depending on the voltage between the source electrode and drain electrode. Accordingly, the transistor including the highly-purified oxide semiconductor film as an active layer has much lower off current than a transistor including silicon having crystallinity. On the other hand, the transistor including silicon having crystallinity has higher mobility and higher on current than the transistor including an oxide semiconductor.

Therefore, when a circuit is formed using semiconductor elements including crystalline silicon, a transistor including an oxide semiconductor is used as a switching element, and supply of a power supply voltage to the circuit is controlled by the switching element, high integration of the integrated circuit and high speed driving thereof can be achieved, and increase of the standby power caused by the leakage current can be suppressed.

Note that as the oxide semiconductor, a four-component metal oxide such as an In—Sn—Ga—Zn—O-based oxide semiconductor; a three-component metal oxide such as an In—Ga—Zn—O-based oxide semiconductor, an In—Sn—Zn—O-based oxide semiconductor, an In—Al—Zn—O-based oxide semiconductor, a Sn—Ga—Zn—O-based oxide semiconductor, an Al—Ga—Zn—O-based oxide semiconductor, and a Sn—Al—Zn—O-based oxide semiconductor; a two-component metal oxide such as an In—Zn—O-based oxide semiconductor, a Sn—Zn—O-based oxide semiconductor, an Al—Zn—O-based oxide semiconductor, a Zn—Mg—O-based oxide semiconductor, a Sn—Mg—O-based oxide semiconductor, an In—Mg—O-based oxide semiconductor, an In—Ga—O-based oxide semiconductor; or an In—O-oxide semiconductor, a Sn—O-based oxide semiconductor, or a Zn—O-based oxide semiconductor; or the like can be used. Note that in this specification, for example, an In—Sn—Ga—Zn—O-based oxide semiconductor means a metal oxide including indium (In), tin (Sn), gallium (Ga), and zinc (Zn), and there is no particular limitation on the composition ratio thereof. The above oxide semiconductor may contain silicon.

Moreover, the oxide semiconductor can be represented by the chemical formula, InMO₃(ZnO)ₘ (m>0). Here, M represents one or more metal elements selected from Ga, Al, Mn, and Co.

The transistor including an oxide semiconductor may be a bottom-gate transistor, a top-gate transistor, or a bottom-contact transistor. The bottom-gate transistor includes a gate electrode over an insulating surface; a gate insulating film over the gate electrode; an oxide semiconductor film which overlaps with the gate electrode over the gate insulating film; a source electrode and a drain electrode over the oxide semiconductor film; and an insulating film over the oxide semiconductor film, the source electrode, and the drain electrode. The top-gate transistor includes an oxide semiconductor film over an insulating surface; a source electrode and a drain electrode over the oxide semiconductor film; a gate insulating film over the oxide semiconductor film, the source electrode, and the drain electrode; a gate electrode which overlaps with the oxide semiconductor film over the gate insulating film; and an insulating film over the gate electrode. The bottom-contact transistor includes a gate electrode over an insulating surface; a gate insulating film over the gate electrode; a source electrode and a drain electrode over the gate insulating film; an oxide semiconductor film which is over the source electrode and the drain electrode and overlaps with the gate electrode over the gate insulating film; and an insulating film over the source electrode, the drain electrode, and the oxide semiconductor film.

By suppressing leakage current of the transistor used as the switching element, high integration of an integrated circuit and high speed driving thereof can be obtained and standby power of the semiconductor device can be reduced.

### BRIEF DESCRIPTION OF DRAWINGS

In the accompanying drawings:

FIG. 1 is a block diagram of a semiconductor device;

FIGS. 2A and 2B each illustrate a structure of a semiconductor device including an inverter and FIG. 2C shows the operation of the semiconductor device;

FIGS. 3A and 3B each illustrate a structure of a semiconductor device including an NAND and FIG. 3C shows the operation of the semiconductor device;

FIGS. 4A and 4B each illustrate a structure of a semiconductor device including a NOR and FIG. 4C shows the operation of the semiconductor device;

FIGS. 5A and 5B illustrate a structure of a semiconductor device including a flip-flop;

FIG. 6A illustrates a structure of a semiconductor device including a flip-flop and FIG. 6B shows the operation thereof;

FIG. 7A illustrates a structure of a semiconductor device including a flip-flop and FIG. 7B shows the operation thereof;

FIGS. 8A to 8E illustrate a method for manufacturing a semiconductor device;

FIGS. 9A to 9D illustrate the method for manufacturing the semiconductor device;

FIGS. 10A and 10B illustrate the method for manufacturing the semiconductor device;

FIGS. 11A to 11D illustrate the method for manufacturing the semiconductor device;

FIGS. 12A to 12C illustrate the method for manufacturing the semiconductor device;

FIGS. 13A to 13C each illustrate a structure of a semiconductor device;

FIGS. 14A and 14B illustrate a structure of a semiconductor display device;

FIG. 15 illustrates a structure of a semiconductor display device;

FIGS. 16A to 16F each illustrate an electronic appliance; and

FIG. 17A illustrates a structure of a semiconductor device including a flip-flop and FIG. 17B shows the operation thereof.

### BEST MODE FOR CARRYING OUT THE INVENTION

Hereinafter, embodiments of the present invention will be described in detail with reference to the accompanying drawings. However, the present invention is not limited to the following description and it is easily understood by those skilled in the art that the mode and details can be variously changed without departing from the scope and spirit of the present invention. Accordingly, the invention should not be construed as being limited to the description of the embodiment modes below.

The present invention can be applied to manufacture of any kind of semiconductor devices including integrated circuits such as microprocessors, image processing circuits, RF tags, and semiconductor display devices. The semiconductor display devices include the following in its category: liquid crystal display devices, light-emitting devices in which a light-emitting element typified by an organic light-emitting element (OLED) is provided for each pixel, electronic paper, digital micromirror devices (DMDs), plasma display panels (PDPs), field emission displays (FEDs), and other semiconductor display devices in which a driver circuit including a semiconductor element is included.

### Embodiment 1

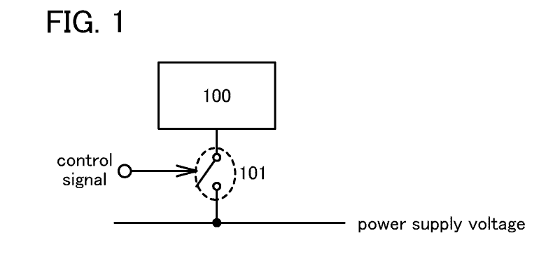

FIG. 1 is a block diagram of a semiconductor device relating to an embodiment of the present invention. A semiconductor device illustrated in FIG. 1 includes a circuit 100 formed with the use of a silicon wafer, an SOI (silicon on insulator) substrate, a silicon thin film over an insulating surface, or the like, and a switching element 101 which controls supply of a power supply voltage to the circuit 100. The switching element 101 performs switching in accordance with a control signal. Specifically, when the circuit 100 is in an operation state, the switching element 101 is turned on in accordance with the control signal, and the power supply voltage is supplied to the circuit 100. In addition, when the circuit 100 is in a stop state, the switching element 101 is turned off in accordance with the control signal, and supply of the power supply voltage to the circuit 100 is stopped.

The circuit 100 includes one or a plurality of semiconductor elements each of which is a minimum unit included in a circuit, such as a transistor, a diode, a capacitor, a resistor, or inductance. Further, a semiconductor included in the semiconductor elements contains silicon having crystallinity (crystalline silicon), such as microcrystalline silicon, polycrystalline silicon, or single crystal silicon.

The circuit 100 may be a basic logic gate such as an inverter, an NAND, a NOR, an AND, or an OR, may be a logic circuit that is a combination of these logic gates, such as a flip-flop, a register, or a shift register, or may be a large-scale arithmetic circuit that is a combination of a plurality of logic circuits.

The switching element 101 includes at least one transistor including an oxide semiconductor as an active layer. In the case where the plurality of transistors is included in the switching element 101, the plurality of transistors may be connected to each other in parallel, in series, or in combination of parallel connection and series connection.

Note that the state in which the transistors are connected to each other in series refers to the state in which only one of a source electrode and a drain electrode of a first transistor is connected to only one of a source electrode and a drain electrode of a second transistor. Further, the state in which the transistors are connected to each other in parallel refers to the state in which the source electrode of the first transistor is connected to the source electrode of the second transistor and the drain electrode of the first transistor is connected to the drain electrode of the second transistor.

The names of the “source electrode” and the “drain electrode” included in the transistor interchange with each other depending on the polarity of the transistor or difference between the levels of potentials applied to the respective electrodes. In general, in an n-channel transistor, an electrode to which a lower potential is applied is called a source electrode, and an electrode to which a higher potential is applied is called a drain electrode. Further, in a p-channel transistor, an electrode to which a lower potential is applied is called a drain electrode, and an electrode to which a higher potential is applied is called a source electrode. In this specification, for convenience, although connection relation of the transistor is described assuming that the source electrode and the drain electrode are fixed; however, actually, the names of the source electrode and the drain electrode interchange with each other depending on relation between the above potentials.

As described above, leakage current of the transistor including an oxide semiconductor is much smaller than that of the transistor including silicon having crystallinity. Therefore, the transistor including an oxide semiconductor is used as the switching element 101 and supply of the power supply voltage to the circuit 100 is controlled by the switching element 101, so that increase of standby power caused by the leakage current of the switching element 101 can be suppressed.

In addition, by reducing power consumption of the circuit 100, a load of another circuit controlling the operation of the circuit 100 can be reduced. Accordingly, functional extension of the circuit 100 and an integrated circuit including another circuit which controls the circuit 100 can be performed as a whole.

On the other hand, in general, the transistor including silicon having crystallinity has higher mobility and higher on current than the transistor including an oxide semiconductor. Therefore, when the circuit 100 is formed using a semiconductor element including crystalline silicon, high integration of the integrated circuit including the circuit 100 and high-speed driving thereof can be achieved.

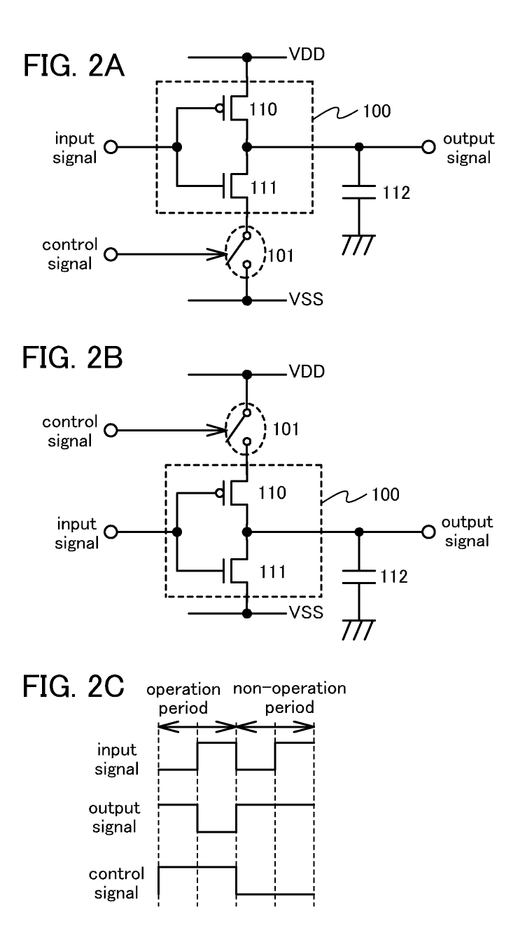

Next, specific structure and operation of the semiconductor device in the case where the circuit 100 is an inverter are described with reference to FIGS. 2A to 2C.

In the semiconductor device illustrated in FIG. 2A, the circuit 100 includes a p-channel transistor 110 and an n-channel transistor 111. In each of the transistor 110 and the transistor 111, silicon having crystallinity is used for an active layer. Further, the transistor 110 and the transistor 111 form an inverter.

Specifically, a drain electrode of the transistor 110 and a drain electrode of the transistor 111 are connected to each other. In addition, the potential of the drain electrode of the transistor 110 and the drain electrode of the transistor 111 is applied to a circuit included in a subsequent stage as the potential of an output signal. A wiring or an electrode to which the output signal is applied includes a capacitance such as a parasitic capacitance. Such a capacitance is referred to as a load 112 in FIG. 2A.

The potential of an input signal is applied to a gate electrode of the transistor 110 and a gate electrode of the transistor 111. A high-level power supply potential VDD is applied to a source electrode of the transistor 110. A low-level power supply voltage VSS is applied to a source electrode of the transistor 111 via the switching element 101.

Note that “connection” in this specification refers to electrical connection and corresponds to the state in which current or voltage can be conducted.

FIG. 2A illustrates the case where the switching element 101 controls supply of the low-level power supply voltage VSS to the circuit 100. Next, FIG. 2B illustrates a structure of a semiconductor device in the case where the switching element 101 controls supply of the high-level power supply voltage VDD to the circuit 100. As in FIG. 2A, in the semiconductor device illustrated in FIG. 2B, the circuit 100 includes the p-channel transistor 110 and the n-channel transistor 111. In each of the transistor 110 and the transistor 111, silicon having crystallinity is used as an active layer. In addition, the transistor 110 and the transistor 111 form an inverter.

Specifically, the drain electrode of the transistor 110 and the drain electrode of the transistor 111 are connected to each other. In addition, the potential of the drain electrode of the transistor 110 and the drain electrode of the transistor 111 is applied to a circuit included in a subsequent stage as the potential of the output signal. A wiring or an electrode to which the output signal is supplied includes a capacitance such as a parasitic capacitance. Such a capacitance is referred to as the load 112 in FIG. 2B.

The potential of the input signal is applied to the gate electrode of the transistor 110 and the gate electrode of the transistor 111. The high-level power supply potential VDD is applied to the source electrode of the transistor 110 via the switching element 101. The low-level power supply voltage VSS is applied to the source electrode of the transistor 111.

The switching element 101 performs switching in accordance with a control signal. By using the semiconductor device illustrated in FIG. 2A as an example, a timing chart of the potentials of the input signal, the output signal, and the control signal in a period in which the circuit 100 is in an operation state (an operation period) and in a period in which the circuit 100 is in a stop state (a non-operation period) is shown in FIG. 2C.

In the operation period, the control signal has a potential with which the switching element 101 is turned on. Specifically, FIG. 2C shows the case where the control signal has a high-level potential. Therefore, in the operation period, the power supply voltage VSS is applied to the source electrode of the transistor 111. Further, when the input signal has a low-level potential, the output signal having a high-level potential can be obtained. When the input signal has a high-level potential, the output signal having a low-level potential can be obtained.

In the non-operation period, the control signal has a potential with which the switching element 101 is turned off. Specifically, FIG. 2C shows the case where the control signal has a low-level potential. Accordingly, in the non-operation period, the power supply voltage VSS is not applied to the source electrode of the transistor 111, and the source electrode of the transistor 111 is in a floating state. Therefore, the potential of the output signal is kept at a high level even when the potential of the input signal is either at a low level or a high level.

As described above, in the non-operation period, by stopping supply of the power supply voltage to the circuit 100, dynamic standby power consumed in the circuit 100 can be reduced. In addition, the switching element 101 is formed using the semiconductor element including an oxide semiconductor film; therefore, static standby power depending on leakage current or the like can be reduced. Therefore, when supply of the power supply voltage to the circuit which is not operated is stopped, both the static standby power and the dynamic standby power consumed in the circuit which is not operated can be reduced, so that it is possible to provide the semiconductor device in which power consumption of the whole circuit can be reduced.

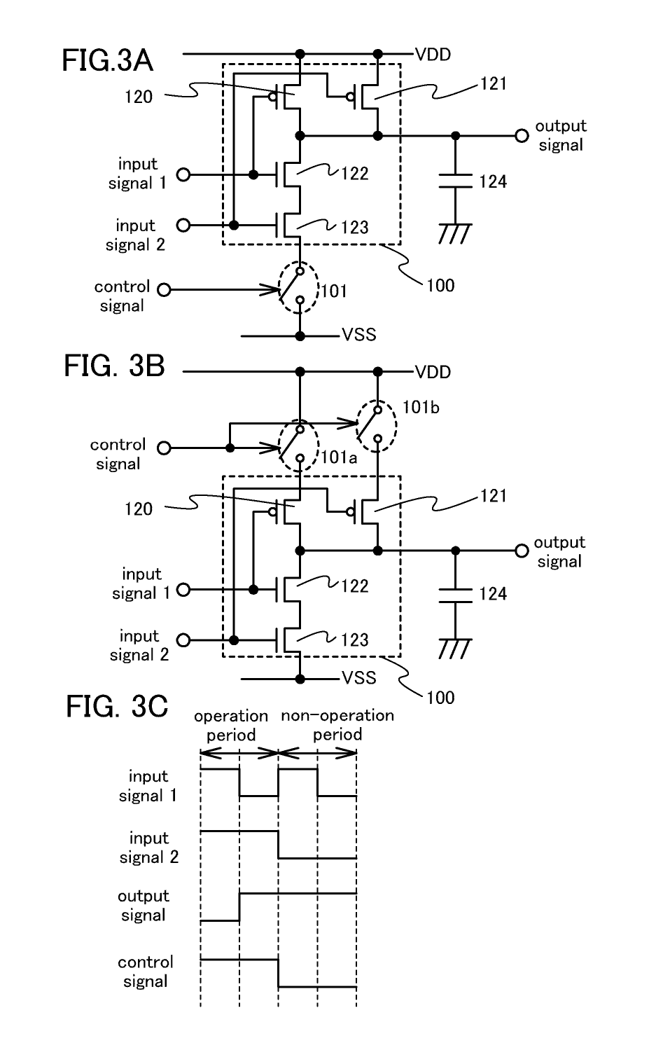

Next, specific structure and operation of the semiconductor device in the case where the circuit 100 is an NAND are described with reference to FIGS. 3A to 3C.

In the semiconductor device illustrated in FIG. 3A, the circuit 100 includes a p-channel transistor 120, a p-channel transistor 121, an n-channel transistor 122, and an n-channel transistor 123. In each of the transistor 120, the transistor 121, the transistor 122, and the transistor 123, silicon having crystallinity is used for an active layer. Further, the transistor 120, the transistor 121, the transistor 122, and the transistor 123 form an NAND.

Specifically, a high-level power supply voltage VDD is applied to a source electrode of the transistor 120 and a source electrode of the transistor 121. The potential of an input signal 1 is applied to a gate electrode of the transistor 120 and a gate electrode of the transistor 122. A drain electrode of the transistor 120, a drain electrode of the transistor 121, and a drain electrode of the transistor 122 are connected to each other, and the potential of these drain electrodes is applied to a circuit included in a subsequent stage, as the potential of an output signal. A wiring or an electrode to which the output signal is applied includes a capacitance such as a parasitic capacitance, and such a capacitance is referred to as a load 124 in FIG. 3A. A source electrode of the transistor 122 and a drain electrode of the transistor 123 are connected to each other. The potential of an input signal 2 is applied to a gate electrode of the transistor 121 and a gate electrode of the transistor 123. Further, a low-level power supply voltage VSS is applied to a source electrode of the transistor 123 via the switching element 101.

FIG. 3A illustrates the case where the switching element 101 controls supply of the low-level power supply voltage VSS to the circuit 100. Next, FIG. 3B illustrates a structure of the semiconductor device in the case where the switching element 101 controls supply of the high-level power supply voltage VDD to the circuit 100. As in FIG. 3A, in the semiconductor device illustrated in FIG. 3B, the circuit 100 includes the p-channel transistor 120, the p-channel transistor 121, the n-channel transistor 122, and the n-channel transistor 123. In each of the transistor 120, the transistor 121, the transistor 122, and the transistor 123, silicon having crystallinity is used as an active layer. In addition, the transistor 120, the transistor 121, the transistor 122, and the transistor 123 form an NAND.

Specifically, the high-level power supply potential VDD is applied to the source electrode of the transistor 120 via a switching element 101a. The high-level power supply voltage VDD is applied to the source electrode of the transistor 121 via a switching element 101b. Note that FIG. 3B illustrates an example in which supply of the power supply voltage VDD to the circuit 100 is controlled by the plurality of switching elements, that is, the switching element 101a and the switching element 101b; however, the number of switching elements may be one. In addition, the potential of the input signal 1 is applied to the gate electrode of the transistor 120 and the gate electrode of the transistor 122. The drain electrode of the transistor 120, the drain electrode of the transistor 121, and the drain electrode of the transistor 122 are connected to each other, and the potential of these drain electrodes is applied to a circuit included in a subsequent stage, as the potential of the output signal. A wiring or an electrode to which the output signal is applied includes a capacitance such as a parasitic capacitance, and such a capacitance is referred to as the load 124 in FIG. 3B. The source electrode of the transistor 122 and the drain electrode of the transistor 123 are connected to each other. The potential of the input signal 2 is applied to the gate electrode of the transistor 121 and the gate electrode of the transistor 123. The low-level power supply voltage VSS is applied to the source electrode of the transistor 123.

The switching element 101 performs switching in accordance with the control signal. By using the semiconductor device illustrated in FIG. 3A as an example, a timing chart of the potentials of the input signals, the output signal, and the control signal in a period in which the circuit 100 is in an operation state (an operation period) and in a period in which the circuit 100 is in a stop state (a non-operation period) is shown in FIG. 3C.

In the operation period, the control signal has potential with which the switching element 101 is turned on. Specifically, FIG. 3C shows the case where the control signal has a high-level potential. Therefore, in the operation period, the power supply voltage VSS is applied to the source electrode of the transistor 123. Further, when the input signal 1 has a high-level potential and the input signal 2 has a high-level potential, the output signal having a low-level potential can be obtained. When the input signal 1 has a low-level potential and the input signal 2 has a high-level potential, the output signal having a high-level potential can be obtained.

In the non-operation period, the control signal has a potential with which the switching element 101 is turned off. Specifically, FIG. 3C shows the case where the control signal has a low-level potential. Accordingly, in the non-operation period, the power supply voltage VSS is not applied to the source electrode of the transistor 123, and the source electrode of the transistor 123 is in a floating state. Therefore, the potential of the output signal is kept at a high level even when the potentials of the input signal 1 and the input signal 2 are either at a low level or at a high level.

As described above, in the non-operation period, by stopping supply of the power supply voltage to the circuit 100, dynamic standby power consumed in the circuit 100 can be reduced. In addition, the switching element 101 is formed using the semiconductor element including an oxide semiconductor film; therefore, static standby power depending on leakage current or the like can be reduced. Therefore, when supply of the power supply voltage to the circuit which is not operated is stopped, both the static standby power and the dynamic standby power consumed in the circuit which is not operated can be reduced, so that it is possible to provide the semiconductor device in which power consumption of the whole circuit can be reduced.

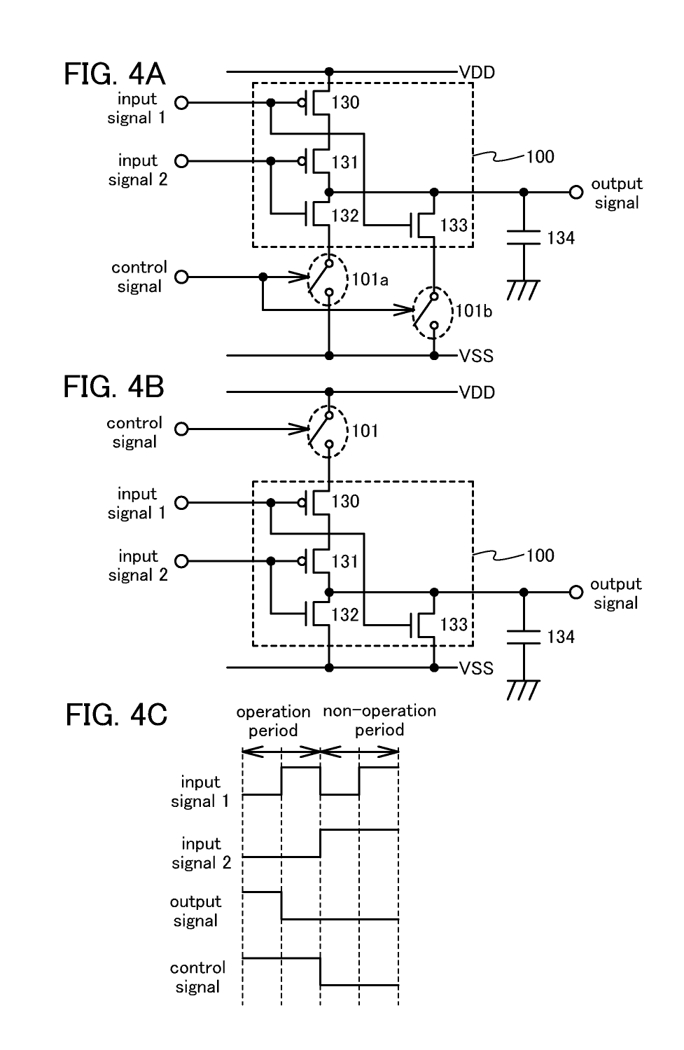

Next, specific structure and operation of the semiconductor device in the case where the circuit 100 is a NOR are described with reference to FIGS. 4A to 4C.

In the semiconductor device illustrated in FIG. 4A, the circuit 100 includes a p-channel transistor 130, a p-channel transistor 131, an n-channel transistor 132, and an n-channel transistor 133. In each of the transistor 130, the transistor 131, the transistor 132, and the transistor 133, silicon having crystallinity is used for an active layer. Further, the transistor 130, the transistor 131, the transistor 132, and the transistor 133 form a NOR.

Specifically, a high-level power supply voltage VDD is applied to a source electrode of the transistor 130. The potential of an input signal 1 is applied to a gate electrode of the transistor 130 and a gate electrode of the transistor 133. A drain electrode of the transistor 130 and a source electrode of the transistor 131 are connected to each other. The potential of the input signal 2 is applied to a gate electrode of the transistor 131 and a gate electrode of the transistor 132. A drain electrode of the transistor 131, a drain electrode of the transistor 132, and a drain electrode of the transistor 133 are connected to each other, and the potential of these drain electrodes is applied to a circuit included in a subsequent stage, as the potential of an output signal. A wiring or an electrode to which the output signal is supplied includes a capacitance such as a parasitic capacitance, and such a capacitance is referred to as a load 134 in FIG. 4A. A low-level power supply voltage VSS is applied to a source electrode of the transistor 132 via the switching element 101a. The low-level power supply voltage VSS is applied to a source electrode of the transistor 133 via the switching element 101b. Note that FIG. 4A illustrates an example in which supply of the power supply voltage VSS to the circuit 100 is controlled by the plurality of switching elements, that is, the switching element 101a and the switching element 101b; however, the number of switching elements may be one.

FIG. 4A illustrates the case where the switching elements 101a and 101b control supply of the low-level power supply voltage VSS to the circuit 100. Next, FIG. 4B illustrates a structure of the semiconductor device in the case where the switching element 101 controls supply of the high-level power supply voltage VDD to the circuit 100. As in FIG. 4A, in the semiconductor device illustrated in FIG. 4B, the circuit 100 includes the p-channel transistor 130, the p-channel transistor 131, the n-channel transistor 132, and the n-channel transistor 133. In each of the transistor 130, the transistor 131, the transistor 132, and the transistor 133, silicon having crystallinity is used as an active layer. In addition, the transistor 130, the transistor 131, the transistor 132, and the transistor 133 form a NOR.

Specifically, the high-level power supply potential VDD is applied to the source electrode of the transistor 130 via the switching element 101. The potential of the input signal 1 is applied to the gate electrode of the transistor 130 and the gate electrode of the transistor 133. The drain electrode of the transistor 130 and the source electrode of the transistor 131 are connected to each other. The potential of the input signal 2 is applied to the gate electrode of the transistor 131 and the gate electrode of the transistor 132. The drain electrode of the transistor 131, the drain electrode of the transistor 132, and the drain electrode of the transistor 133 are connected to each other, and the potential of these drain electrodes is applied to a circuit included in a subsequent stage, as the potential of the output signal. A wiring or an electrode to which the output signal is applied includes a capacitance such as a parasitic capacitance, and such a capacitance is referred to as the load 134 in FIG. 4B. The low-level power supply voltage VSS is applied to the source electrode of the transistor 132 and the source electrode of the transistor 133.

The switching element 101 performs switching in accordance with a control signal. By using the semiconductor device illustrated in FIG. 4A as an example, a timing chart of the potentials of the input signals, the output signal, and the control signal in a period in which the circuit 100 is in an operation state (an operation period) and in a period in which the circuit 100 is in a stop state (a non-operation period) is shown in FIG. 4C.

In the operation period, the control signal has a potential with which the switching element 101a and the switching element 101b are turned on. Specifically, FIG. 4C shows the case where the control signal has high-level potential. Therefore, in the operation period, the power supply voltage VSS is applied to the source electrode of the transistor 132 and the source electrode of the transistor 133. Further, when the input signal 1 has a low-level potential and the input signal 2 has a low-level potential, an output signal having a high-level potential can be obtained. When the input signal 1 has a high-level potential and the input signal 2 has a low-level potential, an output signal having a low-level potential can be obtained.

In the non-operation period, the control signal has a potential with which the switching element 101a and the switching element 101b are turned off. Specifically, FIG. 4C shows the case where the control signal has a low-level potential. Accordingly, in the non-operation period, the power supply voltage VSS is not applied to the source electrode of the transistor 132 and the source electrode of the transistor 133, and the source electrode of the transistor 132 and the source electrode of the transistor 133 are in a floating state. Therefore, the potential of the output signal is kept at a low level even when the potentials of the input signal 1 and the input signal 2 are either at a low level or at a high level.

As described above, in the non-operation period, by stopping supply of the power supply voltage to the circuit 100, dynamic standby power consumed in the circuit 100 can be reduced. In addition, the switching element 101 is formed using the semiconductor element including an oxide semiconductor film; therefore, static standby power depending on leakage current or the like can be reduced. Therefore, when supply of the power supply voltage to the circuit which is not operated is stopped, both the static standby power and the dynamic standby power consumed in the circuit which is not operated can be reduced, so that it is possible to provide the semiconductor device in which power consumption of the whole circuit can be reduced.

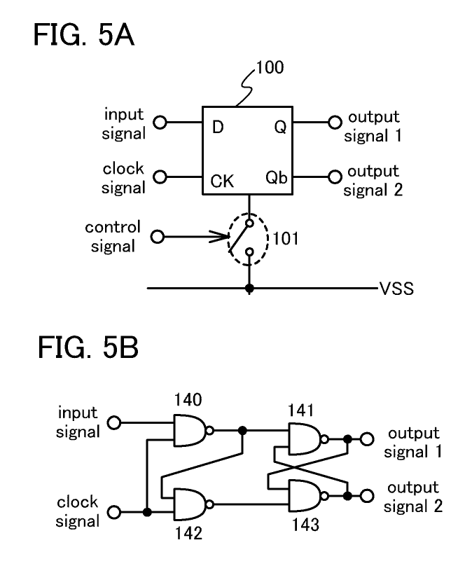

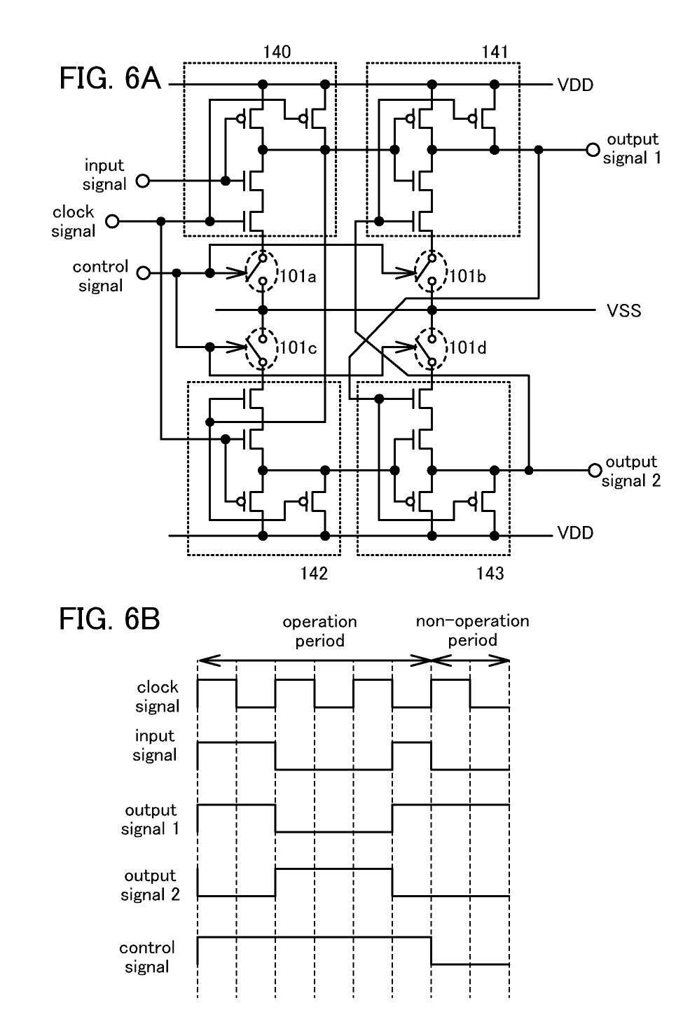

Next, specific structure and operation of the semiconductor device in the case where the circuit 100 is a flip-flop are described as an example with reference to FIGS. 5A and 5B and FIGS. 6A and 6B.

In a semiconductor device illustrated in FIG. 5A, the circuit 100 is a flip-flop, an input signal and a clock signal are input to a terminal D and a terminal CK, respectively, and an output signal 1 and an output signal 2 are output from a terminal Q and a terminal Qb, respectively. There is no limitation on the circuit structure of the flip-flop as long as the circuit can keep one-bit data by utilizing feedback action. FIG. 5B illustrates a more specific structure of the circuit 100. The circuit 100 illustrated in FIG. 5B is a D flip-flop including an NAND 140, an NAND 141, an NAND 142, and an NAND 143. The potential of the input signal is applied to a first input terminal of the NAND 140. The potential of the clock signal is applied to a second input terminal of the NAND 140 and a second input terminal of the NAND 142. An output terminal of the NAND 140 is connected to a first input terminal of the NAND 142 and a first input terminal of the NAND 141. An output terminal of the NAND 142 is connected to a second input terminal of the NAND 143. An output terminal of the NAND 141 is connected to a first input terminal of the NAND 143, and the potential of the output terminal of the NAND 141 is applied, as the potential of the output signal 1, to a circuit included in a subsequent stage. An output terminal of the NAND 143 is connected to a second input terminal of the NAND 141, and the potential of the output terminal of the NAND 143 is applied as the potential of the output signal 2 to the circuit included in the subsequent stage.

Note that the circuit 100 illustrated in FIG. 5B has a structure in which the output signal 1 and the output signal 2 can be obtained; however, the number of output signals may be one as needed.

Then, supply of a power supply voltage to the NAND 140, the NAND 141, the NAND 142, and the NAND 143 is controlled by the switching element 101. FIG. 5A illustrates the case where supply of a low-level power supply voltage VSS is controlled by the switching element 101; however, supply of a high-level power supply voltage may be controlled by the switching element 101.

FIG. 6A illustrates an example of a more specific circuit diagram of the semiconductor device. FIGS. 3A and 3B can be referred to for the connection relation among transistors in the NAND 140, the NAND 141, the NAND 142, and the NAND 143. In each of the transistors included in the NAND 140, the NAND 141, the NAND 142, and the NAND 143, silicon having crystallinity is used as an active layer. Unlike FIG. 5A, FIG. 6A illustrates the case where supply of the power supply voltage VSS to the NAND 140, the NAND 141, the NAND 142, and the NAND 143 is controlled by switching elements 101a, 101b, 101c, and 101d, respectively.

By using the semiconductor device illustrated in FIG. 6A as an example, a timing chart of the potentials of the input signal, the output signals, and a control signal in a period in which the circuit 100 is in an operation state (an operation period) and in a period in which the circuit 100 is in a stop state (a non-operation period) is shown in FIG. 6B. The switching elements 101a to 101d perform switching depending on the control signal.

In the operation period, the control signal has a potential with which the switching elements 101a to 101d are turned on. Specifically, FIG. 6B shows the case where the control signal has a high-level potential. Therefore, in the operation period, the power supply voltage VSS is applied to the NANDs 140 to 143. Further, when the clock signal has a high-level or low-level potential and the input signal has a high-level potential, an output signal 1 having a high-level potential and an output signal 2 having a low-level potential can be obtained. When the clock signal has a high-level or a low-level potential and the input signal has a low-level potential, an output signal 1 having a low-level potential and an output signal 2 having a high-level potential can be obtained.

In the non-operation period, the control signal has potential with which the switching elements 101a to 101d are turned off. Specifically, FIG. 6B shows the case where the control signal has a low-level potential. Accordingly, in the non-operation period, the power supply voltage VSS is not applied to the NANDs 140 to 143. In other words, source electrodes of transistors to each of which the power supply voltage VSS are applied in the operation period is in a floating state in the non-operation period. Therefore, the output signal 1 and the output signal 2 keep their potentials which are the same as those just before the beginning of the non-operation period when the potentials of the clock signal and the input signal are either at a low level or at a high level.

As described above, in the non-operation period, by stopping supply of the power supply voltage to the circuit 100, dynamic standby power consumed in the circuit 100 can be reduced. In addition, the switching element 101 is formed using the semiconductor element including an oxide semiconductor film; therefore, static standby power depending on leakage current or the like can be reduced. Therefore, when supply of the power supply voltage to the circuit which is not operated is stopped, both the static standby power and the dynamic standby power consumed in the circuit which is not operated can be reduced, so that it is possible to provide the semiconductor device in which power consumption of the whole circuit can be reduced.

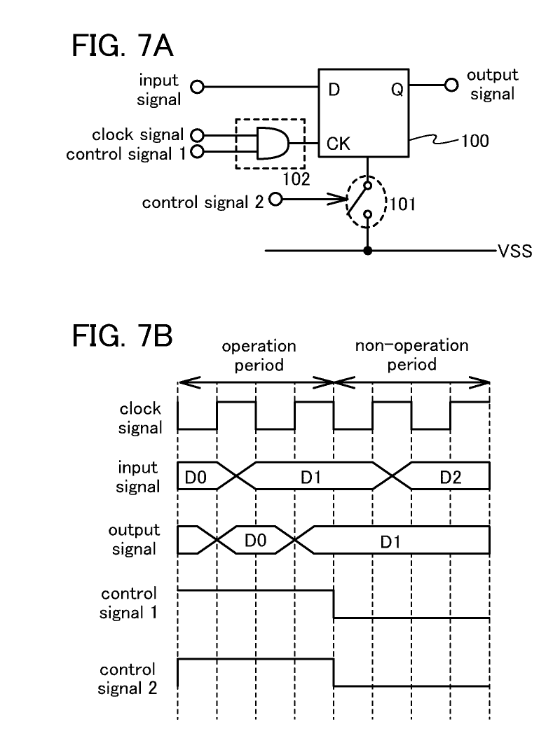

Note that a structure in which supply of the clock signal to the circuit 100 is stopped by a semiconductor element including an oxide semiconductor film when the circuit 100 is in a stop state may be added to the semiconductor device of an embodiment of the present invention. Next, specific structure and operation of the semiconductor device in the case where the circuit 100 is a flip-flop in which supply of a power supply voltage and a clock signal to the circuit 100 can be controlled are described with reference to FIGS. 7A and 7B.

The semiconductor device illustrated in FIG. 7A includes a control circuit 102 which can control supply of a clock signal to the circuit 100, in addition to the circuit 100 and the switching element 101. Besides the clock signal, a control signal 1 for controlling the operation of the control circuit 102 is input to the control circuit 102. FIG. 7A illustrates the case where an AND is used as the control circuit 102, and the clock signal and the control signal both are input to the AND. A signal output from the AND is input to the circuit 100. In addition, the circuit 100 is a flip-flop. An input signal and a signal output from the control circuit 102 are input to a terminal D and a terminal CK, respectively, and an output signal is output from a terminal Q.

FIG. 5B can be referred to for the specific structure of the circuit 100 illustrated in FIG. 7A. There is no limitation on the circuit structure of the flip-flop as long as the circuit can keep one-bit data by utilizing feedback action. In addition, although in the circuit 100 illustrated in FIG. 5B, the output signal 1 and the output signal 2 can be obtained, whereas in the circuit 100 illustrated in FIG. 7A, the number of output signals is one.

Supply of a power supply voltage to the circuit 100 is controlled by the switching element 101. FIG. 7A illustrates the case where supply of a low-level power supply voltage VSS is controlled by the switching element 101; however, supply of a high-level power supply voltage may be controlled by the switching element 101.

FIG. 7A illustrates an example in which the AND is used as the control circuit 102; however, the control circuit 102 is not limited to the AND as long as a circuit structure in which supply of the clock signal to the circuit 100 can be controlled in accordance with the control signal 1 can be obtained. For example, instead of the AND, a NOR may be used as the control circuit 102.

The control circuit 102 includes at least one transistor including an oxide semiconductor film as an active layer. Leakage current of the transistor including an oxide semiconductor film as an active layer is much smaller than that of the transistor including silicon having crystallinity. Therefore, by using the transistor including an oxide semiconductor as the control circuit 102, supply of the clock signal to the circuit 100 is controlled by the control circuit 102, so that increase of standby power due to leakage current of the control circuit 102 can be suppressed.

By using the semiconductor device illustrated in FIG. 7A as an example, a timing chart of data of the input terminal, data of the output terminal, the potential of the control signal 1 and the potential of the control signal 2 in a period in which the circuit 100 is in an operation state (an operation period) and in a period in which the circuit 100 is in a stop state (a non-operation period) is shown in FIG. 7B.

In the operation period, the potential of the control signal 1 is at a high level and the clock signal is supplied to the circuit 100, which is a flip-flop, via the control circuit 102. In addition, the potential of the control signal 2 is at a high level, and the power supply voltage VSS is supplied to the circuit 100. Thus, the circuit 100 is in an operation state. Then, the circuit 100, which is a flip-flop, keeps data on the basis of the clock signal input. In the operation period, since the data included in the input signal is changed from D0 to D1, the data included in the output signal is also changed from D0 to D1.

Next, in the non-operation state, the potential of the control signal 1 is in a low level, and supply of the clock signal to the circuit 100 is stopped. In other words, a potential fixed to a low level is supplied from the control circuit 102 to the circuit 100, which is a flip-flop. Further, in the non-operation period, the potential of the control signal 2 is at a low level, and supply of the power supply voltage VSS to the circuit 100 is stopped. Thus, the circuit 100 is in a non-operation state, the data of the output signal is kept as D1. Note that the state in which supply of the clock signal is stopped refers to the state in which the potential which is applied from the control circuit 102 to circuit 100 in the operation period does not change between a low level and a high level but is fixed at a low level or a high level.

As described above, by stopping supply of the clock signal to the circuit 100, that is, by performing so-called clock gating in the non-operation period, dynamic standby power consumed in the circuit 100 can be reduced. In addition, by stopping supply of the power supply voltage to the circuit 100, the dynamic standby power consumed in the circuit 100 can be reduced. Further, the switching element 101 and the control circuit 102 are formed using semiconductor elements each including an oxide semiconductor film; therefore, static standby power depending on leakage current or the like can be reduced. Accordingly, by stopping supply of the clock signal and the power supply voltage to the circuit which is not operated, both the static standby power and the dynamic standby power consumed in the circuit which is not operated are reduced, so that it is possible to provide the semiconductor device in which power consumption of the whole circuit can be reduced.

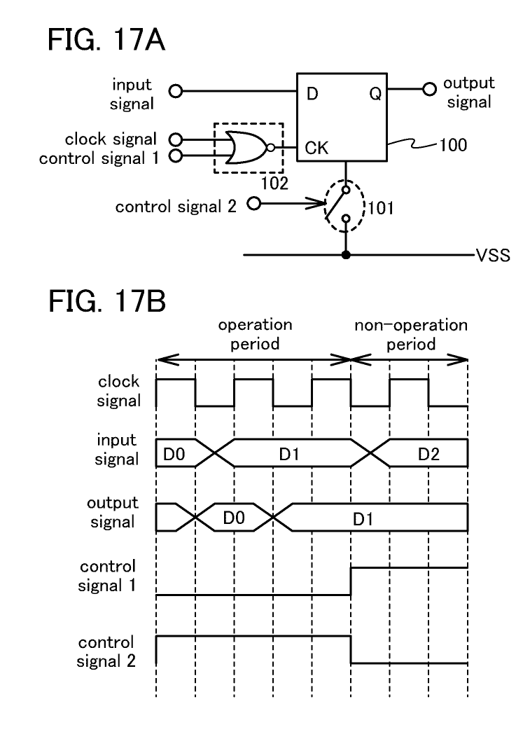

Note that also in the case where a NOR is used as the control circuit 102 instead of an AND, the clock signal and the control signal both are input to the NOR. Then, a signal output from the NOR is input to the circuit 100. FIG. 17A illustrates the case where the NOR is used as the control circuit 102 in the semiconductor device illustrated in FIG. 7A. The structures of the circuit 100 and the switching element 101 are the same as those of FIG. 7A; therefore, detailed description thereof is omitted. By using the semiconductor device illustrated in FIG. 17A as an example, a timing chart of the data of the input signal, the data of the output signal, the potential of the control signal 1 and the potential of the control signal 2 in a period in which the circuit 100 is in an operation state (an operation period) and in a period in which the circuit 100 is in a stop state (a non-operation period) is shown in FIG. 17B.

In the case where the NOR is used as the control circuit 102, in the operation period, the potential of the control signal 1 is at a low level, and the clock signal is supplied to the circuit 100, which is a flip-flop, via the control circuit 102. In addition, the potential of the control signal 2 is at a high level, and the power supply voltage VSS is supplied to the circuit 100. Thus, the circuit 100 is in an operation state. Then, the circuit 100, which is a flip-flop, keeps data on the basis of the clock signal input. In the operation period, since the data included in the input signal is changed from D0 to D1, the data included in the output signal is also changed from D0 to D1.

Next, in the non-operation period, the potential of the control signal 1 is at a high level, and supply of the clock signal to the circuit 100 is stopped. In other words, a potential fixed to a low level is supplied from the control circuit 102 to the circuit 100, which is a flip-flop. Further, in the non-operation period, the potential of the control signal 2 is at a low level, and supply of the power supply voltage VSS to the circuit 100 is stopped. Thus, the circuit 100 is in a non-operation state, and the data of the output signal is kept as D1.

### Embodiment 2

In this embodiment, a method for manufacturing a semiconductor device relating to an embodiment of the present invention will be described.

The semiconductor device relating to an embodiment of the present invention includes a transistor including silicon and a transistor including an oxide semiconductor. The transistor including silicon can be formed using a silicon wafer, an SOI (silicon on insulator) substrate, a silicon thin film over an insulating surface, or the like.

An SOI substrate can be manufactured using, for example, UNIBOND (registered trademark) typified by Smart Cut (registered trademark), epitaxial layer transfer (ELTRAN), a dielectric separation method, a plasma assisted chemical etching (PACE) method, a separation by implanted oxygen (SIMOX) method, or the like.

A semiconductor film of silicon formed over a substrate having an insulating surface may be crystallized by a known technique. As the known technique of crystallization, a laser crystallization method using a laser beam and a crystallization method using a catalytic element are given. Alternatively, a crystallization method using a catalytic element and a laser crystallization method may be combined. In the case of using a thermally stable substrate having a high heat-resisting property such as quartz, it is possible to combine any of the following crystallization methods: a thermal crystallization method with an electrically heated oven, a lamp anneal crystallization method with infrared light, a crystallization method with a catalytic element, and high temperature annealing method at about 950° C.

In addition, a semiconductor element manufactured using the above-described method may be transferred onto a flexible substrate formed of plastic or the like to form a semiconductor device. As the transferring method, the following various methods can be used: a method in which a metal oxide film is provided between the substrate and the semiconductor element, and the metal oxide film is made fragile by crystallization so that the semiconductor element is separated off and transferred; a method in which an amorphous silicon film containing hydrogen is provided between the substrate and the semiconductor element, and the amorphous silicon film is removed by laser-light irradiation or etching so that the semiconductor element is separated off from the substrate and transferred; a method in which the substrate, for which the semiconductor element is provided, is removed by mechanical cutting or etching by a solution or a gas so that the semiconductor element is cut off from the substrate, and the semiconductor element is transferred; and the like.

In this embodiment, an example in which with the use of an SOI (silicon on insulator) substrate, the transistor including silicon is manufactured and then the transistor including an oxide semiconductor is manufactured is given as the method for manufacturing the semiconductor device.

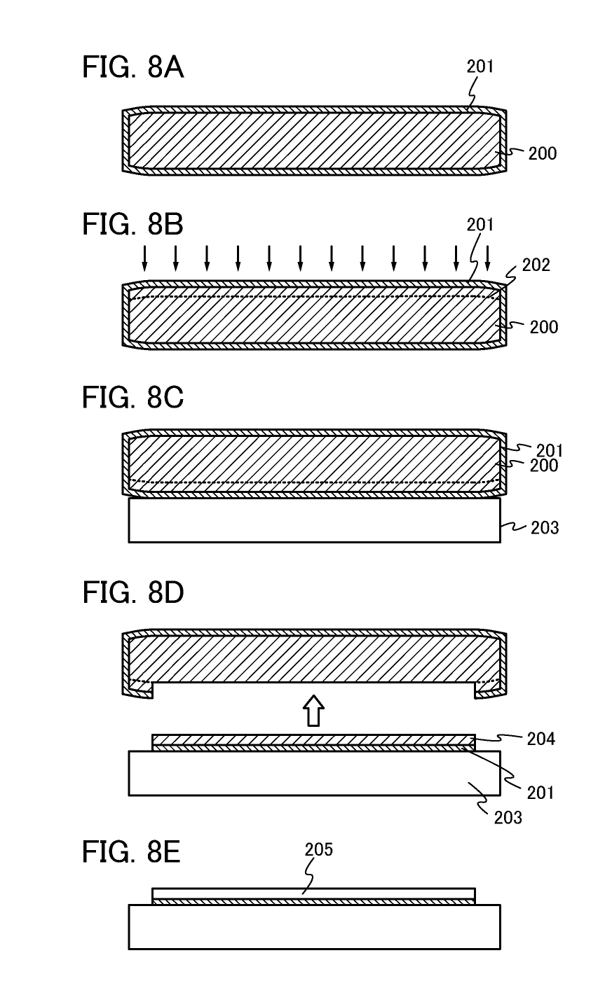

As illustrated in FIG. 8A, a bond substrate 200 is cleaned, and then, an insulating film 201 is formed over a surface of the bond substrate 200.

As the bond substrate 200, a single crystal semiconductor substrate formed using silicon can be used. Further, a semiconductor substrate formed using silicon having crystal lattice distortion, silicon germanium in which germanium is added to silicon, or the like may be used as the bond substrate 200.

Note that in a single crystal semiconductor substrate used for the bond substrate 200, the directions of crystal axes are preferably uniform; however, the substrate is not necessarily formed using perfect crystals in which a lattice defect such as a point defect, a line defect, or a plane defect is completely eliminated.

The shape of the bond substrate 200 is not limited to a circle, and the substrate can be processed into a shape other than a circle. For example, in consideration of the facts that the shape of a base substrate 203 to which the bond substrate 200 is attached later is generally a rectangle and a light exposure region of a light exposure apparatus such as a reduced projection exposure apparatus is rectangular, and the like, the bond substrate 200 may be processed into a rectangular shape. The bond substrate 200 can be processed by cutting a circular single crystal semiconductor substrate available in the market.

The insulating film 201 may be either a single insulating film or stacked layers of a plurality of insulating films. Considering that a region which includes impurities will be removed later, it is preferable to form the insulating film 201 to a thickness of greater than or equal to 15 nm and less than or equal to 500 nm.

As a film included in the insulating film 201, an insulating film containing silicon or germanium as its component such as a silicon oxide film, a silicon nitride film, a silicon oxynitride film, a silicon nitride oxide film, a germanium oxide film, a germanium nitride film, a germanium oxynitride film, or a germanium nitride oxide film can be used. Further, an insulating film including a metal oxide such as aluminum oxide, tantalum oxide, or hafnium oxide; an insulating film including a metal nitride such as aluminum nitride; an insulating film including a metal oxynitride such as an aluminum oxynitride film; or an insulating film including a metal nitride oxide such as an aluminum nitride oxide film can also be used.

For example, in this embodiment, an example in which silicon oxide formed by thermal oxidation of the bond substrate 200 is used as the insulating film 201 is described. Note that in FIG. 8A, the insulating film 201 is formed so as to cover the entire surface of the bond substrate 200; however, the insulating film 201 may be formed on at least one surface of the bond substrate 200.

In this specification, oxynitride refers to a substance which contains more oxygen than nitrogen, and nitride oxide refers to a substance which contains more nitrogen than oxygen.

In the case where the insulating film 201 is formed by thermal oxidation of the surface of the bond substrate 200, dry oxidation in which oxygen containing a small amount of moisture is used, thermal oxidation in which gas containing a halogen such as hydrogen chloride is added to an oxygen atmosphere, or the like can be used as the thermal oxidation. In addition, wet oxidation such as pyrogenic oxidation in which hydrogen is burnt with oxygen to generate water or water vapor oxidation in which high-purity water is heated at 100° C. or higher to generate water vapor and oxidation is performed with use of the water vapor may be used for forming the insulating film 201.

In the case where the base substrate 203 includes an impurity which decreases the reliability of a semiconductor device, such as an alkali metal or an alkaline earth metal, the insulating film 201 preferably includes at least one layer of a barrier film that can prevent such an impurity from diffusing from the base substrate 203 into a semiconductor film which is to be formed after separation. As the insulating film that can be used as the barrier film, a silicon nitride film, a silicon nitride oxide film, an aluminum nitride film, an aluminum nitride oxide film, or the like can be given. The insulating film that is used as the barrier film is preferably formed to a thickness of 15 nm to 300 nm, for example. In addition, an insulating film which has lower proportion of nitrogen than the barrier film, such as a silicon oxide film or a silicon oxynitride film may be formed between the barrier film and the bond substrate 200. The insulating film which has lower proportion of nitrogen may be formed to a thickness of greater than or equal to 5 nm and less than or equal to 200 nm.

In the case of using silicon oxide as the insulating film 201, the insulating film 201 can be formed by a vapor deposition method such as a thermal CVD method, a plasma CVD method, an atmospheric pressure CVD method, or a bias ECRCVD method using a mixed gas of silane and oxygen, a mixed gas of TEOS (tetraethoxysilane) and oxygen, or the like. In this case, a surface of the insulating film 201 may be densified with oxygen plasma treatment. In the case of using silicon nitride for the insulating film 201, the insulating film 201 can be formed using a mixed gas of silane and ammonia by a vapor deposition method such as a plasma CVD method.

Furthermore, the insulating film 201 may be formed using silicon oxide that is formed by a chemical vapor deposition method using an organosilane gas. As an organosilane gas, a silicon-containing compound such as tetraethoxysilane (TEOS) (chemical formula: Si(OC₂H₅)₄), tetramethylsilane (TMS) (chemical formula: Si(CH₃)₄), tetramethylcyclotetrasiloxane (TMCTS), octamethylcyclotetrasiloxane (OMCTS), hexamethyldisilazane (HMDS), triethoxysilane (chemical formula: SiH(OC₂H₅)₃), or trisdimethylaminosilane (chemical formula: SiH(N(CH₃)₂)₃) can be used.

With the use of an organosilane gas for the source gas, a silicon oxide film with a flat surface can be formed at a process temperature of 350° C. or lower. Alternatively, low temperature oxide (LTO) formed at a temperature higher than or equal to 200° C. and lower than or equal to 500° C. by a thermal CVD method can be used. LTO can be formed by using monosilane (SiH₄), disilane (Si₂H₆), or the like as a silicon source gas and using nitrogen dioxide (NO₂) or the like as an oxygen source gas.

For example, in the case of using TEOS and O₂ for the source gas to form the silicon oxide film as the insulating film 201, the condition may be set as follows: the flow rate of TEOS is 15 sccm, the flow rate of O₂ is 750 sccm, the deposition pressure is 100 Pa, the deposition temperature is 300° C., the RF output is 300 W, and the power source frequency is 13.56 MHz.

Note that an insulating film formed at a relatively low temperature, such as a silicon oxide film formed using organosilane or a silicon nitride oxide film formed at a low temperature, has a number of OH groups on its surface. Hydrogen bonding between the OH group and a water molecule forms a silanol group and bonds the base substrate and the insulating film at a low temperature. A siloxane bond, which is a covalent bond, is formed finally between the base substrate and the insulating film. The insulating film such as the aforementioned silicon oxide film formed using organosilane or the LTO formed at a relatively low temperature is suitable for bonding at a low temperature, as compared with a thermally oxidized film having no OH bonds or having very few OH bonds which is used in Smart Cut (registered trademark) or the like.

The insulating film 201 forms a bonding plane which is flat and hydrophilic on the surface of the bond substrate 200. Therefore, the average surface roughness Rₐ of the insulating film 201 is preferably less than or equal to 0.7 nm, more preferably less than or equal to 0.4 nm The thickness of the insulating film 201 may be greater than or equal to 5 nm and less than or equal to 500 nm, preferably greater than or equal to 10 nm and less than or equal to 200 nm.

Next, as illustrated in FIG. 8B, the bond substrate 200 is irradiated with an ion beam including ions accelerated by an electric field through the insulating film 201 as indicated by arrows, whereby an embrittled layer 202 having microvoids is formed in a region at a predetermined depth from the surface of the bond substrate 200. For example, the embrittled layer means a layer which is locally embrittled by disorder of a crystal structure, and the state of the embrittled layer depends on a means for forming the embrittled layer. Note that there may be the case where a region ranging from one surface of the bond substrate to the embrittled layer is embrittled to some extent; however, the embrittled layer in this specification refers to a region at which separation is performed later and its vicinity.

The depth at which the embrittled layer 202 is formed can be adjusted by the acceleration energy of the ion beam and the incident angle thereof. The acceleration energy can be adjusted by acceleration voltage. The embrittled layer 202 is formed at the same depth or substantially the same depth as the average penetration depth of the ions. The thickness of a semiconductor film 204 which will be separated from the bond substrate 200 is determined based on the depth at which the ions are implanted. The depth at which the embrittled layer 202 is formed can be set in the range of, for example, greater than or equal to 50 nm and less than or equal to 500 nm, preferably greater than or equal to 50 nm and less than or equal to 200 nm.

The ions are implanted to the bond substrate 200 desirably by an ion doping method in which mass separation is not performed because the cycle time can be shortened; however, the present invention may employ an ion implantation method in which mass separation is performed.

When hydrogen (H₂) is used for a source gas, H⁺, H₂⁺ and H₃⁺ can be produced by exciting a hydrogen gas. Proportions of ion species produced from the source gas can be changed by controlling a plasma excitation method, the pressure of an atmosphere for producing plasma, the amount of supplied source gas, or the like. In the case where the ion implantation is performed by an ion doping method, it is preferable that H₃⁺ be contained at 50% or more with respect to the total amount of H⁺, H₂⁺, and H₃⁺ in the ion beam, and it is more preferable that the proportion of H₃⁺ be 80% or more. When H₃⁺ is contained at 80% or more, the proportion of H₂⁺ ions in the ion beam gets smaller relatively, which results in lower variation in the average penetration depth of the hydrogen ions contained in the ion beam. Consequently, the ion implantation efficiency improves and the cycle time can be shortened.

H₃⁺ has larger mass than H⁺ and H₂⁺. When the ion beam containing a higher proportion of H₃⁺ is compared with the ion beam containing a higher proportion of H⁺ and H₂⁺, the former can implant hydrogen into a shallower region of the bond substrate 200 than the latter even if the acceleration voltage at the time of doping is the same. Moreover, the former has a steep concentration distribution of hydrogen implanted into the bond substrate 200 in a thickness direction, therefore, the embrittled layer 202 itself can be formed to be thinner.

In the case of performing ion implantation by an ion doping method with the use of a hydrogen gas, the acceleration voltage is set to be greater than or equal to 10 kV and less than or equal to 200 kV and the dosage is set to be greater than or equal to 1×10¹⁶ ions/cm² and less than or equal to 6×10¹⁶ ions/cm². Under this condition, the embrittled layer 202 can be formed in a region at a depth of greater than or equal to 50 nm and less than or equal to 500 nm of the bond substrate 200, though depending on the ion species included in the ion beam and its proportion, and the film thickness of the insulating film 201.

For example, in the case where the bond substrate 200 is a single crystal silicon substrate and the insulating film 201 is formed using a 100-nm-thick thermal oxide film, a semiconductor film with a thickness of approximately 146 nm can be separated from the bond substrate 200 under the condition where the flow rate of 100% hydrogen gas, which is the source gas, is 50 sccm, the beam current density is 5 μA/cm², the acceleration voltage is 50 kV, and the dosage is 2.0×10¹⁶ atoms/cm². Note that even if the condition at the time of adding hydrogen to the bond substrate 200 is not changed, when the thickness of the insulating film 201 is made larger, the thickness of the semiconductor film can be made smaller.

Helium (He) can alternatively be used as the source gas of the ion beam. Since most of the ion species produced by exciting helium are He⁺, He⁺ can be mainly implanted into the bond substrate 200 even by an ion doping method in which mass separation is not performed. Therefore, microvoids can be formed in the embrittled layer 202 efficiently by an ion doping method. In the case of performing ion addition by an ion doping method using helium, the acceleration voltage can be greater than or equal to 10 kV and less than or equal to 200 kV, and the dose can be greater than or equal to 1×10¹⁶ ions/cm² and less than or equal to 6×10¹⁶ ions/cm².

A halogen gas such as a chlorine gas (Cl₂ gas) or a fluorine gas (F₂ gas) can be used for the source gas.

In the case where ions are implanted into the bond substrate 200 by an ion doping method, impurities existing in an ion doping apparatus are implanted together with the ions to a processing object; therefore, there is a possibility that impurities such as S, Ca, Fe, and Mo exist on and near the surface of the insulating film 201. Therefore, a region on and near the surface of the insulating film 201 where the number of impurities is considered to be the largest may be removed by etching, polishing, or the like. Specifically, a region at a depth of 10 nm to 100 nm, preferably, approximately 30 nm to 70 nm from the surface of the insulating film 201 may be removed. The dry etching may employ, for example, a reactive ion etching (RIE) method, an inductively coupled plasma (ICP) etching method, an electron cyclotron resonance (ECR) etching method, a parallel-plate (capacitively coupled plasma) etching method, a magnetron plasma etching method, a dual-frequency plasma etching method, a helicon wave plasma etching method, or the like. For example, in the case of removing a region on and near a surface of a silicon nitride oxide film by an ICP etching method, the region can be removed to a depth of about 50 nm from the surface under the condition where the flow rate of CHF₃ as an etching gas is 7.5 sccm, the flow rate of He is 100 sccm, the reaction pressure is 5.5 Pa, the temperature of a lower electrode is 70° C., the RF (13.56 MHz) electric power applied to a coil-shaped electrode is 475 W, the electric power applied to the lower electrode (on bias side) is 300 W, and the etching time is about 10 seconds.

Instead of CHF₃, which is a fluorine-based gas, a chlorine-based gas such as Cl₂, BCl₃, SiCl₄, or CCl₄; another fluorine-based gas such as CF₄, SF₆, or NF₃; or O₂ can be used as appropriate for the etching gas. Moreover, an inert gas other than He may be added to the etching gas. For example, one or plural elements selected from Ne, Ar, Kr, or Xe can be used as the inert element which is added to the etching gas. In the case of removing a region on and near a surface of a silicon nitride oxide film by wet etching, a fluorinated acid based solution including ammonium hydrogen fluoride, ammonium fluoride, or the like may be used as an etchant. The polishing can be performed by CMP (chemical mechanical polishing), liquid jet polishing, or the like.

After the formation of the embrittled layer 202, the region on and near the surface of the insulating film 201 where the contamination is remarkable is removed by etching, polishing, or the like, whereby the amount of impurities which enter the semiconductor film 204 formed over the base substrate 203 can be suppressed. Moreover, in a semiconductor device which is completed finally, it is possible to prevent the impurities from causing decrease in reliability and decrease in electrical characteristics of transistors, such as variation in threshold voltage or increase in leakage current.

Next, as illustrated in FIG. 8C, the bond substrate 200 and the base substrate 203 are attached to each other with the insulating film 201 therebetween.

Note that before the base substrate 203 and the bond substrate 200 are attached to each other, surface treatment for improving the bonding strength between the insulating film 201 and the base substrate 203 is preferably performed on surfaces for bonding, that is, in this embodiment, surfaces of the base substrate 203 and the insulating film 201 formed over the bond substrate 200.

As examples of the surface treatment, wet treatment, dry treatment, and combination of wet treatment and dry treatment can be given. Different wet treatments or different dry treatments may be combined to be performed. Examples of the wet treatment include ozone treatment using ozone water (ozone water cleaning), ultrasonic cleaning such as megasonic cleaning, two-fluid cleaning (a method in which functional water such as pure water or hydrogenated water and a carrier gas such as nitrogen are sprayed together), cleaning with hydrochloric acid and a hydrogen peroxide solution, and the like. As examples of the dry treatment, inert gas neutral atomic beam treatment, inert gas ion beam treatment, ultraviolet treatment, ozone treatment, plasma treatment, plasma treatment with bias application, radical treatment, and the like can be given. By performing the above-described surface treatment, the hydrophilicity and cleanliness of the surfaces for attaching can be increased. Thus, the bonding strength can be improved.

For the attaching, the base substrate 203 and the insulating film 201 formed over the bond substrate 200 are disposed in close contact with each other, and then, a pressure of approximately 1 N/cm² to 500 N/cm², preferably, 11 N/cm² to 20 N/cm² is applied to part of the base substrate 203 and the bond substrate 200 which are superposed on each other. When the pressure is applied, bonding between the base substrate 203 and the insulating film 201 starts from the portion, which results in bonding between entire surfaces of the base substrate 203 and the insulating film 201 which are in close contact with each other.

The bonding is performed by Van der Waals force or a hydrogen bond, so that the bonding is firm even at room temperature. Note that since the above-described bonding can be performed at a low temperature, a variety of substrates can be used for the base substrate 203. For example, a variety of glass substrates for electronics industry, such as an alumino silicate glass substrate, a barium borosilicate glass substrate, or an aluminoborosilicate glass substrate, a quartz substrate, a ceramic substrate, a sapphire substrate, or the like can be used as the base substrate 203. As the base substrate 203, alternatively, a semiconductor substrate formed of silicon, gallium arsenide, indium phosphide, or the like can be used. Further alternatively, a metal substrate including a stainless steel substrate may be used as the base substrate 203. Substrates with coefficients of thermal expansion of greater than or equal to 25×10⁻⁷/° C. and less than or equal to 50×10⁻⁷/° C. (preferably, greater than or equal to 30×10⁻⁷/° C. and less than or equal to 40×10⁻⁷/° C.) and strain points of greater than or equal to 580° C. and less than or equal to 680° C. (preferably, greater than or equal to 600° C. and less than or equal to 680° C.) are preferably used as the glass substrate which serves as the base substrate 203. When the glass substrate is an alkali-free glass substrate, impurity contamination of semiconductor devices can be suppressed.

As the glass substrate, a mother glass substrate developed for production of liquid crystal panels can be used. As a mother glass substrate, substrates having the following sizes are known: the third generation (550 mm×650 mm), the 3.5-th generation (600 mm×720 mm), the fourth generation (680 mm×880 mm, or 730 mm×920 mm), the fifth generation (1100 mm×1300 mm), the sixth generation (1500 mm×1850 mm), the seventh generation (1870 mm×2200 mm), the eighth generation (2200 mm×2400 mm), and the like. Size increase of an SOI substrate can be realized by using a large-area substrate such as a mother glass substrate, as the base substrate 203. Increasing the area of the SOI substrate enables many chips such as ICs or LSIs to be manufactured all at once, and thus the number of chips manufactured from one substrate is increased; therefore, productivity can be dramatically increased.

If the base substrate 203 is a glass substrate that largely shrinks when heat treatment is performed thereon, such as EAGLE 2000 (manufactured by Corning Incorporated), defective in attachment may occur after the bonding step. Therefore, in order to avoid such defective bonding that is caused by the shrink, the base substrate 203 may be subjected to heat treatment in advance before the bonding step.

Moreover, an insulating film may be formed in advance over the base substrate 203. The base substrate 203 is not necessarily provided with an insulating film on its surface. However, the formation of the insulating film on the surface of the base substrate 203 can prevent impurities of the base substrate 203, such as an alkali metal and an alkaline earth metal, from entering the bond substrate 200. Moreover, in the case of forming the insulating film on the surface of the base substrate 203, the insulating film over the base substrate 203 is bonded to the insulating film 201; therefore, a wider variety of substrates can be used as the base substrate 203. In general, the upper temperature limits of substrates formed of flexible synthetic resins such as plastics tend to be low. However, as long as the substrates can resist process temperatures in manufacturing steps of a semiconductor element performed later, the substrates formed of such resins can be used as the base substrate 203 in the case of forming the insulating film over the base substrate 203. Examples of a plastic substrate include polyester typified by polyethylene terephthalate (PET), polyethersulfone (PES), polyethylene naphthalate (PEN), polycarbonate (PC), polyetheretherketone (PEEK), polysulfone (PSF), polyetherimide (PEI), polyarylate (PAR), polybutylene terephthalate (PBT), polyimide, acrylonitrile-butadiene-styrene resin, polyvinyl chloride, polypropylene, polyvinyl acetate, acrylic resin, and the like. In the case of forming the insulating film over the base substrate 203, the attachment of the base substrate 203 and the bond substrate 200 to each other is preferably performed after surface treatment is performed on the surface of this insulating film in a manner similar to the insulating film 201.

After the bond substrate 200 is attached to the base substrate 203, heat treatment is preferably performed in order to increase the bonding force at the bonding interface between the base substrate 203 and the insulating film 201. This treatment is performed at a temperature where a crack is not generated in the embrittled layer 202 and can be performed at a temperature in the range of higher than or equal to 200° C. and lower than or equal to 400° C. By attaching the bond substrate 200 to the base substrate 203 within this temperature range, the bonding force between the base substrate 203 and the insulating film 201 can be strengthened.

If the bonding plane is contaminated by dust or the like at the time of attaching the bond substrate 200 and the base substrate 203 to each other, the contaminated portion is not bonded. In order to avoid the contamination of the bonding plane, the bond substrate 200 and the base substrate 203 are preferably attached to each other in an airtight chamber. At the time of attaching the bond substrate 200 and the base substrate 203 to each other, the process chamber may have pressure reduced to approximately 5.0×10⁻³ Pa and the atmosphere of the bonding process may be cleaned.

Next, heat treatment is performed, whereby microvoids which are adjacent to each other in the embrittled layer 202 are combined and the volume of the microvoids increases. As a result, as illustrated in FIG. 8D, the semiconductor film 204 which is part of the bond substrate 200 is separated from the bond substrate 200 along the embrittled layer 202. Since the insulating film 201 and the base substrate 203 are bonded to each other, the semiconductor film 204 which is separated from the bond substrate 200 is fixed to the base substrate 203. The heat treatment for separating the semiconductor film 204 from the bond substrate 200 is preferably performed at a temperature which does not exceed the strain point of the base substrate 203.

For this heat treatment, a rapid thermal annealing (RTA) apparatus, a resistance heating furnace, or a microwave heating apparatus can be used. For the RTA apparatus, a gas rapid thermal annealing (GRTA) apparatus or a lamp rapid thermal annealing (LRTA) apparatus can be used. When a GRTA apparatus is used, a heating temperature can be set at a temperature of higher than or equal to 550° C. and lower than or equal to 650° C., and processing time can be set at greater than or equal to 0.5 minute and less than or equal to 60 minutes. In the case of using a resistance heating apparatus, the heating temperature can be set at a temperature higher than or equal to 200° C. and lower than or equal to 650° C., and processing time can be set at greater than or equal to 2 hours and less than or equal to 4 hours.

The heat treatment may be performed by dielectric heating with a high-frequency wave such as a microwave. The heat treatment by dielectric heating can be performed by irradiating the bond substrate 200 with a high-frequency wave with a frequency of 300 MHz to 3 THz generated by a high-frequency wave generation apparatus. Specifically, for example, irradiation with a microwave with a frequency of 2.45 GHz at 900 W is performed for 14 minutes to combine microvoids adjacent to each other in the embrittled layer, whereby the bond substrate 200 can be split along the embrittled layer finally.

A specific treatment method of a heat treatment using a vertical furnace having resistive heating is described. The base substrate 203 to which the bond substrate 200 is attached is disposed on a boat of the vertical furnace and this boat is delivered in a chamber of the vertical furnace. In order to suppress oxidation of the bond substrate 200, the chamber is evacuated first such that a vacuum state is formed. The degree of vacuum is approximately 5×10⁻³ Pa. After a vacuum state is obtained, nitrogen is supplied to the chamber so that the chamber has a nitrogen atmosphere under atmospheric pressure. In this period, the heat temperature is increased to 200° C.

After the chamber is made to have a nitrogen atmosphere under atmospheric pressure, heating is performed at 200° C. for two hours. Then, the temperature is increased to 400° C. in one hour. After the state at a heating temperature of 400° C. is stabilized, the temperature is increased to 600° C. in one hour. After a state in which the heating temperature is 600° C. becomes stable, heat treatment is performed at 600° C. for two hours. Then, the temperature is decreased to 400° C. in one hour, and after 10 minutes to 30 minutes, the boat is carried out from the chamber. The base substrate 203 to which the bond substrate 200 and the semiconductor film 204 are attached and which is disposed on the boat is cooled under an atmospheric atmosphere.

The heat treatment using the above resistance heating furnace is performed by successively performing heat treatment for strengthening the bonding force between the insulating film 201 and the base substrate 203 and heat treatment for splitting the embrittled layer 202. In the case of performing these two kinds of heat treatment in different apparatuses, for example, heat treatment is performed at 200° C. for two hours in a resistance heating furnace and then the base substrate 203 and the bond substrate 200 which are attached to each other are carried out from the furnace. Next, heat treatment is performed by an RTA apparatus at a process temperature higher than or equal to 600° C. and lower than or equal to 700° C. for one minute to several hours, so that the bond substrate 200 is split along the embrittled layer 202.

Note that in some cases, the periphery of the bond substrate 200 is not bonded to the base substrate 203. It is likely that this is because the periphery of the bond substrate 200 is chamfered or has a curvature, so that the base substrate 203 and the insulating film 201 are not in close contact with each other or the embrittled layer 202 is difficult to split at the periphery of the bond substrate 200. Another reason is that polishing such as CMP performed in manufacturing the bond substrate 200 is insufficient at the periphery of the bond substrate 200, so that a surface thereof is rougher at the periphery than at a center. Still another reason is that, in the case where a carrier or the like damages the periphery of the bond substrate 200 at the time of delivery of the bond substrate 200, the damage makes it difficult to bond the periphery to the base substrate 203. For these reasons, the semiconductor film 204 which is smaller than the bond substrate 200 is attached to the base substrate 203.

Note that the bond substrate 200 may be subjected to hydrogenation treatment before the bond substrate 200 is split. Hydrogenation is performed, for example, at 350° C. for about 2 hours in a hydrogen atmosphere.

If a plurality of bond substrates 200 are attached to the base substrate 203, the plurality of bond substrates 200 may have different crystal plane orientation. The mobility of majority carriers in a semiconductor depends on crystal plane orientation. Therefore, the semiconductor film 204 may be formed by selecting as appropriate the bond substrate 200 which has crystal plane orientation suitable for a semiconductor element to be formed. For example, in the case of forming an n-type semiconductor element with the use of the semiconductor film 204, the formation of the semiconductor film 204 with a {100} plane can increase the mobility of majority carriers in the semiconductor element. On the other hand, for example, in the case of forming a p-type semiconductor element with the use of the semiconductor film 204, the formation of the semiconductor film 204 with a {110} plane can increase the mobility of majority carriers in the semiconductor element. Then, in the case of forming a transistor as a semiconductor element, the bonding direction of the semiconductor film 204 is determined in consideration of a channel direction and crystal plane orientation.

Next, a surface of the semiconductor film 204 may be planarized by polishing. Although the planarization is not necessarily essential, the planarization makes it possible to improve characteristics of the interface between a gate insulating film and semiconductor films 206 and 207 which are to be formed later. Specifically, the polishing may be chemical mechanical polishing (CMP), liquid jet polishing, or the like. The thickness of the semiconductor film 204 is decreased by the planarization. The planarization may be performed on the semiconductor film 204 before being etched; alternatively, the planarization may be performed on the semiconductor films 206 and 207 formed by etching.

Not the polishing but etching may be performed on the surface of the semiconductor film 204 in order to planarize the surface of the semiconductor film 204. The etching may be performed using a dry etching method, for example, reactive ion etching (RIE), inductively coupled plasma (ICP) etching, electron cyclotron resonance (ECR) etching, parallel-plate (capacitively coupled type) etching, magnetron plasma etching, dual-frequency plasma etching, or helicon wave plasma etching.

For example, when ICP etching is used, etching may be performed under the following conditions: the flow rate of chlorine, which is an etching gas is 40 sccm to 100 sccm; power applied to a coil type electrode is 100 W to 200 W; the power applied to a lower electrode (on the bias side) is 40 W to 100 W; and the reaction pressure is 0.5 Pa to 1.0 Pa. For example, the thickness of the semiconductor film 204 can be reduced to about 50 nm to 60 nm by performing the etching under the condition where the flow rate of chlorine as an etching gas is 100 sccm, the reaction pressure is 1.0 Pa, the temperature of the lower electrode is 70° C., the RF (13.56 MHz) electric power applied to the coil-shaped electrode is 150 W, the electric power applied to the lower electrode (on the bias side) is 40 W, and the etching time is about 25 seconds to 27 seconds. For the etching gas, a chlorine-based gas such as chlorine, boron chloride, silicon chloride or carbon tetrachloride; a fluorine-based gas such as carbon tetrafluoride, sulfur fluoride, or nitrogen fluoride; or oxygen is used as appropriate.

By the etching, the thickness of the semiconductor film 204 can be reduced to be optimal for a semiconductor element to be formed later and the surface of the semiconductor film 204 can be planarized, as well.

Note that in the semiconductor film 204 bonded to the base substrate 203, crystal defects are formed due to the formation of the embrittled layer 202 and the split along the embrittled layer 202, and thus planarity of the surface of the semiconductor film 204 is impaired. Thus, in one embodiment of the present invention, in order to reduce crystal defects and improve planarity, the semiconductor film 204 is irradiated with laser beam after a process of removing an oxide film such as a natural oxide film which is formed on the surface of the semiconductor film 204.

In this embodiment of the present invention, the semiconductor film 204 is immersed in DHF having a hydrogen fluoride concentration of 0.5 wt % for 110 seconds, whereby the oxide film is removed.

The laser beam irradiation is preferably performed with such an energy density that the semiconductor film 204 is partially melted. This is because if the semiconductor film 204 is completely melted, generation of microcrystals due to recrystallization of the semiconductor film 204 is accompanied with disordered nucleation of the semiconductor film 204 in a liquid phase and crystallinity of the semiconductor film 204 is lowered. By partly melting, so-called longitudinal growth in which crystal growth proceeds from an unmelted solid portion occurs in the semiconductor film 204. Due to the recrystallization by the longitudinal growth, crystal defects of the semiconductor film 204 are reduced and crystallinity thereof is recovered. The state in which the semiconductor film 204 is completely melted indicates the state in which the semiconductor film 204 is melted to be in a liquid phase to the interface with the insulating film 201. On the other hand, the state in which the semiconductor film 204 is partly melted indicates the state in which an upper part thereof is melted and is in a liquid phase and a lower part thereof is in a solid phase.

As this laser beam irradiation, pulsed laser beam irradiation is preferable for partly melting the semiconductor film 204. For example, in the case of a pulsed laser, the repetition rate is less than or equal to 1 MHz and the pulse width is greater than or equal to 10 nanoseconds and less than or equal to 500 nanoseconds. A XeCl excimer laser with a repetition rate of 10 Hz to 300 Hz, a pulse width of 25 nanoseconds, and a wavelength of 308 nm can be used, for example.

As the laser beam, a fundamental wave or a second harmonic of a solid-state laser, which is selectively absorbed by a semiconductor, is preferably used. Specifically, for example, laser beam having a wavelength in the range of greater than or equal to 250 nm and less than or equal to 700 nm can be used. The energy of the laser beam can be determined in consideration of the wavelength of the laser beam, the skin depth of the laser beam, the thickness of the semiconductor film 204, or the like. For example, in the case where the thickness of the semiconductor film 204 is approximately 120 nm and a pulsed laser that emits laser beam having a wavelength of 308 nm is used, the energy density of the laser beam may be set to 600 mJ/cm² to 700 mJ/cm².

As a pulsed laser, an Ar laser, a Kr laser, an excimer laser, a CO₂ laser, a YAG laser, a Y₂O₃ laser, a YVO₄ laser, a YLF laser, a YAlO₃ laser, a glass laser, a ruby laser, an alexandrite laser, a Ti:sapphire laser, a copper-vapor laser, or a gold-vapor laser can be used.

In this embodiment, in the case where the thickness of the semiconductor film 204 is approximately 146 nm, the laser beam irradiation can be performed in the following manner. As a laser emitting laser beam, a XeCl excimer laser (wavelength: 308 nm, pulse width: 20 nanoseconds, and repetition rate: 30 Hz) is used. The cross section of the laser beam is shaped into a linear form with a size of 0.4 mm×120 mm through an optical system. The semiconductor film 204 is irradiated with the laser beam with laser scanning speed of 0.5 mm/s. Then, through the laser beam irradiation, a semiconductor film 205 whose crystal defects have been repaired is formed as illustrated in FIG. 8E.

Note that the laser beam irradiation is preferably performed in an inert atmosphere such as a rare gas atmosphere or a nitrogen atmosphere, or a reduced-pressure atmosphere. In the case of the above atmosphere, the laser beam irradiation may be performed in an airtight chamber whose atmosphere is controlled.

If the chamber is not used, the laser beam irradiation in an inert atmosphere can be achieved by spraying an inert gas such as a nitrogen gas to the surface to be irradiated with the laser beam. The laser beam irradiation is performed in an inert atmosphere or a reduced-pressure atmosphere instead of an air atmosphere, whereby the natural oxide film is further prevented from being formed, cracks or pitch stripes can be prevented from being formed in the semiconductor film 205 which is formed after the laser beam irradiation, planarity of the semiconductor film 205 can be improved, and the applicable energy range for the laser beam can be widened.

The laser beam preferably has its cross section shaped of a linear form with homogenous energy distribution through an optical system. Accordingly, the laser beam irradiation can be performed homogenously at high throughput. With the beam length of the laser beam longer than one side of the base substrate 203, the entire semiconductor film 204 attached to the base substrate 203 can be irradiated with the laser beam by scanning once. When the beam length of the laser beam is shorter than one side of the base substrate 203, the beam length may be set so that the entire semiconductor film 204 attached to the base substrate 203 can be irradiated with the laser beam by scanning a plurality of times.

In order to perform the laser beam irradiation in a reduced-pressure atmosphere or an inert atmosphere such as a rare gas atmosphere or a nitrogen atmosphere, the laser beam irradiation may be performed in an airtight chamber whose atmosphere is controlled. If the chamber is not used, the laser beam irradiation in an inert atmosphere can be achieved by spraying an inert gas such as a nitrogen gas to the surface to be irradiated with the laser beam. The laser beam irradiation is performed in an inert atmosphere or a reduced-pressure atmosphere instead of an air atmosphere, whereby the natural oxide film is further prevented from being formed, cracks or pitch stripes can be prevented from being formed in the semiconductor film 205 which is formed after the laser beam irradiation, planarity of the semiconductor film 205 can be improved, and the applicable energy range for the laser beam can be widened.

In the case where the surface of the semiconductor film 204 is planarized by dry etching before the laser beam irradiation, damages such as crystal defects might be generated on and near the surface of the semiconductor film 204 due to the dry etching. However, the aforementioned laser beam irradiation can recover even the damages caused by the dry etching.

Next, after the laser beam irradiation, the surface of the semiconductor film 205 may be etched. If the surface of the semiconductor film 205 is etched after the laser beam irradiation, the surface of the semiconductor film 204 is not necessarily etched before the laser beam irradiation. Moreover, if the surface of the semiconductor film 204 is etched before the laser beam irradiation, the surface of the semiconductor film 205 is not necessarily etched after the laser beam irradiation. Alternatively, the surface of the semiconductor film 205 may be etched after the laser beam irradiation and before the laser beam irradiation.

The etching can not only thin the semiconductor film 205 to the thickness optimum for a semiconductor element to be formed later but also planarize the surface of the semiconductor film 205.

After the laser beam irradiation, the semiconductor film 205 is preferably subjected to heat treatment at a temperature higher than or equal to 500° C. and lower than or equal to 650° C. This heat treatment can eliminate defects of the semiconductor film 205 which have not been repaired by the laser beam irradiation and can reduce distortion of the semiconductor film 205. For this heat treatment, a rapid thermal annealing (RTA) apparatus, a resistance heating furnace, or a microwave heating apparatus can be used. For the RTA apparatus, a gas rapid thermal annealing (GRTA) apparatus or a lamp rapid thermal annealing (LRTA) apparatus can be used. For example, when a resistance heating furnace is used, a heat treatment may be performed at 600° C. for 4 hours.

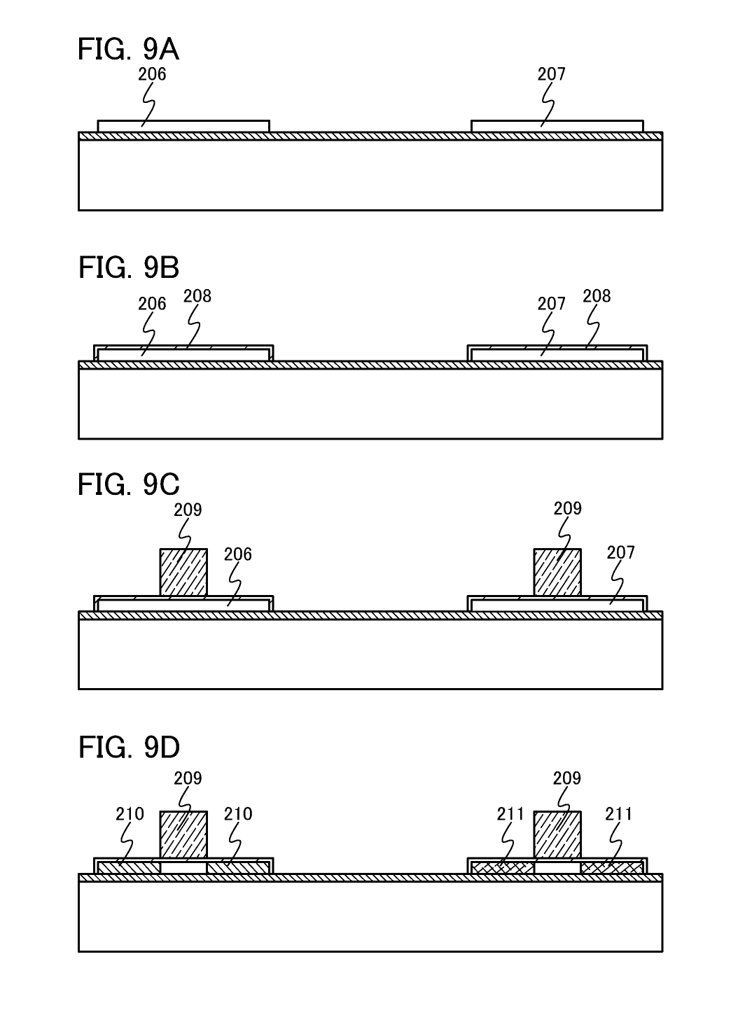

Next, as illustrated in FIG. 9A, the semiconductor film 205 is partly etched to form the island-shaped semiconductor films 206 and 207. When the semiconductor film 205 is further etched, edge portions of the semiconductor film 205 which do not have enough bonding strength can be removed. Although the semiconductor films 206 and 207 are formed by etching one semiconductor film 205 in this embodiment mode, the number of semiconductor films which are formed is not limited to two.

Note that the surface of the bond substrate 200 from which the semiconductor film 204 is separated is planarized, whereby a semiconductor film 204 can be separated again from the bond substrate 200.

Specifically, the insulating film 201 which remains mainly at edge portions of the bond substrate 200 is removed by etching or the like. In the case where the insulating film 201 is formed using silicon oxide, silicon oxynitride, silicon nitride oxide, or the like, wet etching using hydrofluoric acid can be employed.

Next, projections formed at the edge portions of the bond substrate 200 due to the separation of the semiconductor film 204 and the remaining embrittled layer which contains hydrogen excessively are removed. For the etching of the bond substrate 200, wet etching is preferably used, and a tetramethylammonium hydroxide (abbreviation: TMAH) solution can be used as an etchant.

Then, the surface of the bond substrate 200 is polished. For the polishing, CMP can be used. To smooth the surface of the bond substrate 200, the surface is desirably polished by approximately 1 μm to 10 μm in thickness. After the polishing, RCA cleaning using hydrofluoric acid or the like is performed because abrasive particles and the like are left on the surface of the bond substrate 200.

By reusing the bond substrate 200, the cost of a material of the semiconductor substrate can be reduced.

To control threshold voltage, a p-type impurity element such as boron, aluminum, or gallium or an n-type impurity element such as phosphorus or arsenic may be added to the semiconductor film 206 and the semiconductor film 207. The addition of the impurity for controlling the threshold voltage may be performed on the semiconductor film before being patterned or may be performed on the semiconductor film 206 and the semiconductor film 207 which are formed by the patterning. Alternatively, the impurity for controlling the threshold voltage may be added to a bond substrate. Alternatively, the addition of the impurity may be performed on the bond substrate in order to roughly control the threshold voltage, and the addition of the impurity may be further performed on the semiconductor film before being patterned or the semiconductor film 206 and the semiconductor film 207 which are formed by the patterning in order to finely control the threshold voltage.

Next, gate insulating films 208 are formed to cover the semiconductor film 206 and the semiconductor film 207, as illustrated in FIG. 9B. Surfaces of the semiconductor film 206 and the semiconductor film 207 are oxidized or nitrided by high-density plasma treatment, whereby the gate insulating films 208 can be formed. The high-density plasma treatment is performed, for example, by using a mixed gas of an inert gas such as He, Ar, Kr, or Xe, and oxygen, nitrogen oxide, ammonia, nitrogen, hydrogen, or the like. In this case, by performing excitation of plasma with introduction of a microwave, plasma with a low electron temperature and high density can be generated. The surfaces of the semiconductor films are oxidized or nitrided by oxygen radicals (which include OH radicals in some cases) or nitrogen radicals (which include NH radical in some cases) produced by such high-density plasma, whereby insulating films of 1 nm to 20 nm thick, desirably 5 nm to 10 nm thick, is formed in contact with the semiconductor films. This insulating film of 5 nm to 10 nm thick is used for the gate insulating films 208. For example, nitrous oxide (N₂O) is diluted with Ar by 1 to 3 times (flow ratio) and a microwave (2.45 GHz) electric power of 3 kW to 5 kW is applied with a pressure of 10 Pa to 30 Pa to oxidize or nitride the surfaces of the semiconductor film 206 and the semiconductor film 207. By this treatment, an insulating film having a thickness of 1 nm to 10 nm (preferably 2 nm to 6 nm) is formed. Further, nitrous oxide (N₂O) and silane (SiH₄) are introduced and microwaves (2.45 GHz) electric power of 3 to 5 kW is applied with a pressure of 10 to 30 Pa to form a silicon oxynitride film by a vapor-phase growth method, which is to be a gate insulating film. With a combination of a solid-phase reaction and a reaction by a vapor deposition method, the gate insulating film with low interface state density and excellent withstand voltage can be formed.

Since the oxidation or nitridation of the semiconductor films by the high-density plasma treatment is a solid-phase reaction, the interface state density between the gate insulating film 208 and each of the semiconductor film 206 and the semiconductor film 207 can be drastically decreased. Further, since the semiconductor film 206 and the semiconductor film 207 are directly oxidized or nitrided by the high-density plasma treatment, variation in thickness of the insulating film to be formed can be suppressed. Moreover, in the case where the semiconductor film has crystallinity, the surface of the semiconductor film is oxidized with solid reaction by the high-density plasma treatment to restrain fast oxidation only in a crystal grain boundary; therefore, the gate insulating film with uniformity and low interface state density can be formed. Transistors in each of which the insulating film formed by the high-density plasma treatment is included in a part of or the entire gate insulating film may reduce variations in a characteristic.

Alternatively, the gate insulating films 208 may be formed by thermally oxidizing the semiconductor film 206 and the semiconductor film 207. The gate insulating films 208 may be formed as a single layer or a stack of plural layers of a film containing silicon oxide, silicon nitride oxide, silicon oxynitride, silicon nitride, hafnium oxide, aluminum oxide, or tantalum oxide by a plasma CVD method, a sputtering method, or the like.

Then, after forming a conductive film over the gate insulating films 208, the conductive film is processed (patterned) into a predetermined shape, whereby electrodes 209 are formed over the semiconductor film 206 and the semiconductor film 207 as illustrated in FIG. 9C. A CVD method, a sputtering method, or the like may be used for forming the conductive film. As the conductive film, tantalum (Ta), tungsten (W), titanium (Ti), molybdenum (Mo), aluminum (Al), copper (Cu), chromium (Cr), niobium (Nb), or the like may be used. Moreover, an alloy containing the above-mentioned metal as a main component or a compound containing the above-mentioned metal may be used. Alternatively, the conductive film may be formed from a semiconductor such as polycrystalline silicon doped with an impurity element such as phosphorus which imparts conductivity to the semiconductor film.

In a case of forming a two-layer conductive film, a first layer can be formed of tantalum nitride or tantalum and a second layer can be formed of tungsten. Moreover, the following combinations are given: tungsten nitride and tungsten, molybdenum nitride and molybdenum, aluminum and tantalum, aluminum and titanium, and the like. Since tungsten and tantalum nitride have high heat resistance, heat treatment for thermal activation can be performed in a step after forming the two-layer conductive film. Alternatively, as the combination of the two-layer conductive film, silicon doped with an impurity which imparts n-type conductivity and nickel silicide, silicon doped with an impurity which imparts n-type conductivity and tungsten silicide, or the like can be used.

In addition, although the electrodes 209 are formed of a single-layer conductive film in this embodiment, this embodiment is not limited to this structure. The electrodes 209 may be formed of a plurality of conductive films which is stacked. In the case of using a three-layer structure in which three conductive films are stacked, a stacked structure of a molybdenum film, an aluminum film, and a molybdenum film is preferable.

Note that the electrodes 209 may be selectively formed by a droplet discharge method without using a mask.

Note that a droplet discharge method is a method in which a predetermined pattern is formed by discharging or ejecting droplets containing a predetermined composition and an ink-jet method is included in the category.

Further, after the conductive film is formed, the electrodes 209 can be etched into a desired tapered shape by using an inductively coupled plasma (ICP) etching method and appropriately controlling the etching condition (e.g., the amount of electric power applied to a coiled electrode layer, the amount of electric power applied to an electrode layer on the substrate side, or the electrode temperature on the substrate side). In addition, angles and the like of the tapered shape may also be controlled by a shape of a mask. Note that as an etching gas, a chlorine-based gas such as chlorine, boron chloride, silicon chloride, or carbon tetrachloride; a fluorine-based gas such as carbon tetrafluoride, sulfur fluoride, or nitrogen fluoride; or oxygen can be used as appropriate.

Subsequently, as illustrated in FIG. 9D, impurity elements imparting one conductivity type are added to the semiconductor film 206 and the semiconductor film 207 by using the electrodes 209 as masks. In this embodiment, an impurity element which imparts n-type conductivity (e.g., phosphorus or arsenic) is added to the semiconductor film 206, and an impurity element which imparts p-type conductivity (e.g., boron) is added to the semiconductor film 207. It is to be noted that when the p-type impurity element is added to the semiconductor film 207, the semiconductor film 206 to which the n-type impurity element is added is covered with a mask or the like so that the p-type impurity element is added selectively. In an opposite manner, when the n-type impurity element is added to the semiconductor film 206, the semiconductor film 207 to which the p-type impurity element is added is covered with a mask or the like so that the n-type impurity element is added selectively. Alternatively, after an impurity element imparting one of the p-type conductivity and the n-type conductivity is added to the semiconductor film 206 and the semiconductor film 207, an impurity element imparting the other conductivity may be selectively added to one of the semiconductor film 206 and the semiconductor film 207 at a higher concentration than that of the previously added impurity element. By the addition of the impurity, impurity regions 210 are formed in the semiconductor film 206 and impurity regions 211 are formed in the semiconductor film 207.

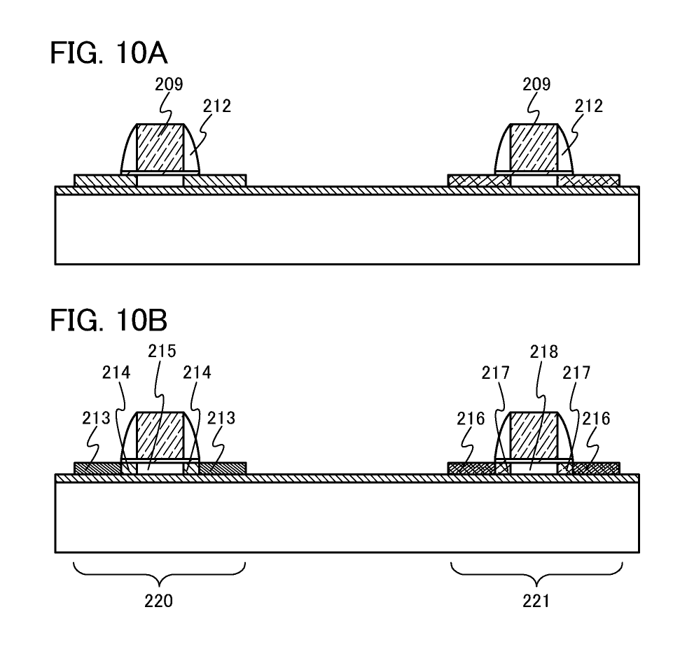

Next, as illustrated in FIG. 10A, sidewalls 212 are formed on side surfaces of the electrodes 209. For example, the sidewalls 212 can be formed in such a manner that an insulating film is newly formed so as to cover the gate insulating film 208 and the electrodes 209 and the insulating film is partially etched by anisotropic etching in which etching is performed mainly in a perpendicular direction. The newly-formed insulating film is partially etched by the anisotropic etching, whereby the sidewalls 212 are formed on the side surfaces of the electrodes 209. Note that the gate insulating film 208 may also be partially etched by the aforementioned anisotropic etching. The insulating film for forming the sidewalls 212 can be formed of a single layer or a stack of layers of a silicon film, a silicon oxide film, a silicon oxynitride oxide film, a silicon nitride oxide film, or a film including an organic material such as an organic resin by an LPCVD method, a plasma CVD method, a sputtering method, or the like. In this embodiment, a 100-nm-thick silicon oxide film is formed by a plasma CVD method. As the etching gas, a mixed gas of CHF₃ and helium can be used. Note that the process for forming the sidewalls 212 is not limited to this process described above.

Next, as illustrated in FIG. 10B, an impurity element imparting one conductivity type is added to the semiconductor film 206 and the semiconductor film 207 with the electrodes 209 and the sidewalls 212 used as masks. Note that the impurity elements imparting the same conductivity type as the impurity elements which have been added in the previous step are added to the semiconductor film 206 and the semiconductor film 207 at a higher concentration than in the previous step. Note that when the p-type impurity element is added to the semiconductor film 207, the semiconductor film 206 to which the n-type impurity element is added is covered with a mask or the like so that the p-type impurity element is added selectively. In an opposite manner, when the n-type impurity element is added to the semiconductor film 206, the semiconductor film 207 to which the p-type impurity element is added is covered with a mask or the like so that the n-type impurity element is added selectively.

By the addition of the impurity elements, a pair of high-concentration impurity regions 213, a pair of low-concentration impurity regions 214, and a channel formation region 215 are formed in the semiconductor film 206. Further, by the addition of the impurity element, a pair of high-concentration impurity regions 216, a pair of low-concentration impurity regions 217, and a channel formation region 218 are formed in the semiconductor film 207. The high-concentration impurity regions 213 and the high-concentration impurity regions 216 serve as source and drain regions, and the low-concentration impurity regions 214 and the low-concentration impurity regions 217 serve as LDD (lightly doped drain) regions. Note that the LDD regions are not necessarily provided, and only impurity regions serve as source and drain regions may be formed. Alternatively, the LDD region may be formed on either the source region side or the drain region side.

Note that the sidewalls 212 formed over the semiconductor film 207 and the sidewalls 212 formed over the semiconductor film 206 may have the same widths in a carrier moving direction or may have different widths in the carrier moving direction. It is preferable that the width of the sidewall 212 over the semiconductor film 207 which is included in a p-channel transistor be larger than the width of the sidewall 212 over the semiconductor film 206 which is included in an n-channel transistor. This is because boron which is added for forming a source region and a drain region in the p-channel transistor is easily diffused and a short channel effect is easily induced. When the width of each sidewall 212 in the p-channel transistor is made larger than that of each sidewall 212 in the n-channel transistor, boron can be added to the source region and the drain region at high concentration, and thus the resistance of the source region and the drain region can be reduced.

Next, in order to further reduce the resistance of the source region and the drain region, silicide is formed in the semiconductor film 206 and the semiconductor film 207, so that silicide layers may be formed. The silicide is formed in such a manner that a metal is brought into contact with the semiconductor films, and silicon in the semiconductor films is made to react with the metal by heat treatment, a GRTA method, an LRTA method, or the like. The silicide layer may be formed of cobalt silicide or nickel silicide. In the case where the thickness of each of the semiconductor film 206 and the semiconductor film 207 is small, silicide formation may be proceed to the bottom portions of the semiconductor film 206 and the semiconductor film 207. As a metal material used for the silicide formation, the following can be used: titanium (Ti), nickel (Ni), tungsten (W), molybdenum (Mo), cobalt (Co), zirconium (Zr), hafnium (Hf), tantalum (Ta), vanadium (V), neodymium (Nd), chromium (Cr), platinum (Pt), palladium (Pd), or the like. Alternatively, the silicide may be formed by laser beam irradiation, light irradiation using a lamp, or the like.

Through the above steps, an n-channel transistor 220 and a p-channel transistor 221 are formed.

After the step illustrated in FIG. 10B is completed, a transistor including an oxide semiconductor is manufactured over the transistor 220 and the transistor 221.

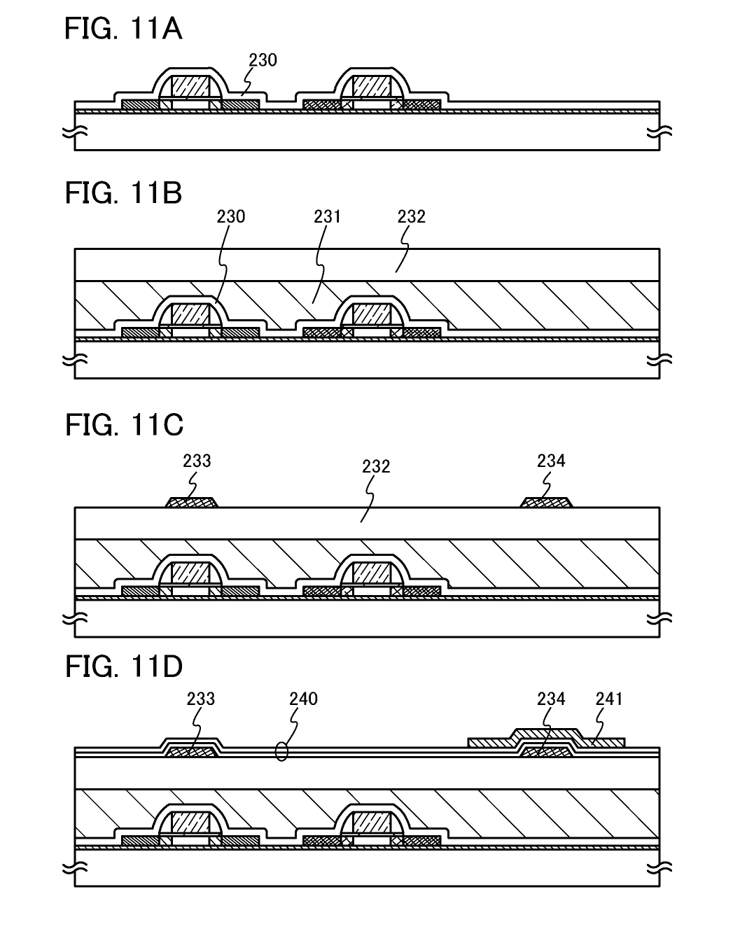

First, as illustrated in FIG. 11A, an insulating film 230 is formed to cover the transistor 220 and the transistor 221. By providing the insulating film 230, oxidation of surfaces of the electrodes 209 can be prevented when heat treatment is performed. In particular, the insulating film 230 is preferably formed using silicon nitride, silicon oxynitride, silicon nitride oxide, aluminum nitride, aluminum oxide, silicon oxide, or the like. In this embodiment, a silicon oxynitride film having a thickness of approximately 50 nm is used as the insulating film 230.

Next, as illustrated in FIG. 11B, an insulating film 231 and an insulating film 232 are formed over the insulating film 230 to cover the transistor 220 and the transistor 221. The insulating film 231 and the insulating film 232 are formed using materials which can withstand a temperature of heat treatment in a later manufacturing step. Specifically, an inorganic insulating film of silicon oxide, silicon nitride, silicon nitride oxide, silicon oxynitride, aluminum nitride, aluminum nitride oxide, or the like can be used for the insulating film 231 and the insulating film 232, for example.

Note that the insulating film 231 and the insulating film 232 are stacked over the insulating film 230 in this embodiment; however, the insulating film formed over the insulating film 230 may be an insulating film of a single layer or an insulating layer in which three or more layers are stacked.

A surface of the insulating film 232 may be planarized by a CMP method or the like.

Next, as illustrated in FIG. 11C, a conductive film is formed over the insulating film 232, and then unnecessary portions are removed by etching, so that a wiring 233 and a gate electrode 234 are formed. At that time, etching is performed such that at least an edge portion of the gate electrode 234 is formed in a tapered shape.

The conductive film can be formed to have a single-layer structure or a stacked-layer structure using a metal material such as molybdenum, titanium, chromium, tantalum, tungsten, neodymium, or scandium; an alloy material which contains any of these metal materials as its main component; or a nitride which contains any of these metals. Note that aluminum or copper can also be used as the above metal material as long as it can withstand the temperature of heat treatment performed later.

For example, as a two-layer structure of the conductive film, the following structures are preferable: a two-layer structure in which a molybdenum layer is stacked over an aluminum layer, a two-layer structure in which a molybdenum layer is stacked over a copper layer, a two-layer structure in which a titanium nitride layer or a tantalum nitride layer is stacked over a copper layer, and a two-layer structure of a titanium nitride layer and a molybdenum layer. As a three-layer structure, the following structure is preferable: a stacked-layer structure including aluminum, an alloy of aluminum and silicon, an alloy of aluminum and titanium, or an alloy of aluminum and neodymium in a middle layer and any of tungsten, tungsten nitride, titanium nitride, and titanium in a top layer and a bottom layer.

At that time, a light-transmitting oxide conductive film is used for part of the electrode and the wiring to increase the aperture ratio. For example, indium oxide, an alloy of indium oxide and tin oxide, an alloy of indium oxide and zinc oxide, zinc oxide, zinc aluminum oxide, zinc aluminum oxynitride, zinc gallium oxide, or the like can be used for the oxide conductive film.

The thickness of each of the wiring 233 and the gate electrode 234 is 10 nm to 400 nm, preferably 100 nm to 200 nm In this embodiment, after a conductive film with a thickness of 100 nm for the gate electrode is formed by a sputtering method using a tungsten target, the conductive film is processed (patterned) by etching to have a desired shape, so that the wiring 233 and the gate electrode 234 are formed.

Then, as illustrated in FIG. 11D, a gate insulating film 240 is formed over the wiring 233 and the gate electrode 234. The gate insulating film 240 is formed using a film having a single layer or a stacked layer which includes a silicon oxide film, a silicon nitride film, a silicon oxynitride film, a silicon nitride oxide film, a hafnium oxide film, an aluminum oxide film, or a tantalum oxide film by plasma CVD, sputtering, or the like. It is preferable that the gate insulating film 240 includes impurities such as moisture, hydrogen, or oxygen as little as possible. The gate insulating film 240 may have a structure in which an insulating film formed using a material having a high barrier property and an insulating film formed using a silicon oxide film, a silicon oxynitride film, or the like which has lower proportion of nitrogen are stacked. In this case, the insulating film formed using a silicon oxide film, a silicon oxynitride film, or the like is formed between the insulating film having a barrier property and the oxide semiconductor film. As the insulating film having a barrier property, for example, a silicon nitride film, a silicon nitride oxide film, an aluminum nitride film, an aluminum nitride oxide film, or the like can be given. By using the insulating film having a barrier property, impurities in an atmosphere, such as moisture and hydrogen, or impurities included in the substrate, such as an alkali metal and a heavy metal can be prevented from entering the oxide semiconductor film, the gate insulating film 240, or an interface between the oxide semiconductor film and another insulating film and the vicinity thereof. In addition, when the insulating film having lower proportion of nitrogen, such as a silicon oxide film or a silicon oxynitride film is formed in contact with the oxide semiconductor film, the insulating film formed using the material having a high barrier property can be prevented from being directly in contact with the oxide semiconductor film.

In this embodiment, the insulating film 240 has a structure in which a silicon oxide film with a thickness of 100 nm formed by sputtering method is stacked over a silicon nitride film with a thickness of 50 nm formed by a sputtering method.

Next, an oxide semiconductor film is formed over the gate insulating film 240 and processed into a desired shape by etching or the like, so that an island-shaped oxide semiconductor film 241 is formed so as to overlap with the gate electrode 234. The oxide semiconductor film is formed by a sputtering method using an oxide semiconductor target. Moreover, the oxide semiconductor film can be formed by a sputtering method in a rare gas (for example, argon) atmosphere, an oxygen atmosphere, or an atmosphere containing a rare gas (for example, argon) and oxygen.

Note that before the oxide semiconductor film is formed by a sputtering method, dust and a contaminant attached to a surface of the gate insulating film 240 is preferably removed by reverse sputtering in which an argon gas is introduced and plasma is generated. The reverse sputtering refers to a method in which, without application of voltage to a target side, a surface of a substrate is modified in such a manner that an RF power source for voltage application is used to a substrate side under an argon atmosphere and an argon ion is collided with the substrate. Note that instead of an argon atmosphere, a nitrogen atmosphere, a helium atmosphere, or the like may be used. Alternatively, an argon atmosphere to which oxygen, nitrous oxide, or the like is added may be used. Alternatively, an argon atmosphere to which chlorine, carbon tetrafluoride, or the like is added may be used.

An oxide material having semiconductor characteristics as described above may be used for the oxide semiconductor film for forming a channel formation region.

The thickness of the oxide semiconductor film is set to be 10 nm to 300 nm, preferably 20 nm to 100 nm In this embodiment, deposition is performed using a target for forming an oxide semiconductor containing In, Ga, and Zn (in a molar ratio, In₂O₃:Ga₂O₃:ZnO=1:1:1 or In₂O₃:Ga₂O₃:ZnO=1:1:2) under the following conditions: the distance between a substrate and a target is 100 mm, the pressure is 0.6 Pa, the direct-current (DC) power supply is 0.5 kW, and the atmosphere is oxygen (the flow rate of oxygen is 100%). Note that a pulse direct current (DC) power supply is preferable because dust can be reduced and the film thickness can be uniform. In this embodiment, as the oxide semiconductor film, an In—Ga—Zn—O-based non-single-crystal film having a thickness of 30 nm is formed using the In—Ga—Zn—O-based oxide semiconductor target with a sputtering apparatus.

Note that when the oxide semiconductor film is formed without exposure to the air after the plasma treatment, dust or moisture can be prevented from attaching to an interface between the gate insulating film 240 and the oxide semiconductor film. Further, a pulsed direct current (DC) power source is preferable because dust can be reduced and a thickness distribution is uniform.

It is preferable that the relative density of the oxide semiconductor target is greater than or equal to 80%, more preferably, greater than or equal to 95%, further preferably, greater than or equal to 99.9%. The impurity concentration of the oxide semiconductor film which is formed using the target having high relative density can be reduced, and thus a thin film transistor having high electric characteristics or high reliability can be obtained.

In addition, there is also a multi-source sputtering apparatus in which a plurality of targets of different materials can be set. With the multi-source sputtering apparatus, films of different materials can be formed to be stacked in the same chamber, or a film of plural kinds of materials can be formed by electric discharge at the same time in the same chamber.

In addition, there are a sputtering apparatus provided with a magnet system inside the chamber and used for a magnetron sputtering, and a sputtering apparatus used for an ECR sputtering in which plasma generated with the use of microwaves is used without using glow discharge.

Furthermore, as a deposition method by sputtering, there are also a reactive sputtering method in which a target substance and a sputtering gas component are chemically reacted with each other during deposition to form a thin compound film thereof, and a bias sputtering in which a voltage is also applied to a substrate during deposition.

In addition, the substrate may be heated at a temperature higher than or equal to 100° C. and lower than or equal to 700° C. by light or a heater during the deposition with a sputtering method. The damage due to sputtering is repaired at the same time as the deposition by heating during the deposition.

Preheat treatment is preferably performed so as to remove moisture or hydrogen remaining on an inner wall of the sputtering apparatus, on a surface of the target, or in a target material, before the oxide semiconductor film is formed. As the preheat treatment, a method in which the inside of the deposition chamber is heated to from 200° C. to 600° C. under a reduced pressure, a method in which introduction and exhaust of nitrogen or an inert gas are repeated while the inside of the deposition chamber is heated, and the like can be given. After the preheat treatment, the substrate or the sputtering apparatus is cooled, and then the oxide semiconductor film is formed without exposure to air. In this case, not water but oil or the like is preferably used as a coolant for the target. Although a certain level of effect can be obtained when introduction and exhaust of nitrogen are repeated without heating, it is more preferable to perform the treatment with the inside of the deposition chamber heated.

It is preferable to remove moisture or the like remaining in the sputtering apparatus with the use of a cryopump before, during, or after the oxide semiconductor film is formed.

The island-shaped oxide semiconductor film 241 can be formed using wet etching in which, for example, a mixed solution of phosphoric acid, acetic acid, and nitric acid is used. The island-shaped oxide semiconductor film 241 is formed so as to overlap with the gate electrode 234. In etching of the oxide semiconductor film, organic acid such as citric acid or oxalic acid can be used for etchant. In this embodiment, unnecessary portions are removed by wet etching using ITO07N (product of Kanto Chemical Co., Inc.), so that the island-shaped oxide semiconductor film 241 is formed. Note that the etching performed here may be dry etching instead of wet etching.

As the etching gas for dry etching, a gas containing chlorine (chlorine-based gas such as chlorine (Cl₂), boron chloride (BCl₃), silicon chloride (SiCl₄), or carbon tetrachloride (CCl₄)) is preferably used.

Alternatively, a gas containing fluorine (fluorine-based gas such as carbon tetrafluoride (CF₄), sulfur fluoride (SF₆), nitrogen fluoride (NF₃), or trifluoromethane (CHF₃)); hydrogen bromide (HBr); oxygen (O₂); any of these gases to which a rare gas such as helium (He) or argon (Ar) is added; or the like can be used.

As the dry etching method, a parallel plate RIE (reactive ion etching) method or an ICP (inductively coupled plasma) etching method can be used. In order to etch the film into desired shapes, the etching condition (the amount of electric power applied to a coil-shaped electrode, the amount of electric power applied to an electrode on a substrate side, the temperature of the electrode on the substrate side, or the like) is adjusted as appropriate.

The etchant after the wet etching is removed together with the etched materials by cleaning. The waste liquid including the etchant and the material etched off may be purified and the material may be reused. When a material such as indium included in the oxide semiconductor film is collected from the waste liquid after the etching and reused, the resources can be efficiently used and the cost can be reduced.

In order to obtain a desired shape by etching, the etching conditions (such as an etchant, etching time, and temperature) are adjusted as appropriate depending on the material.

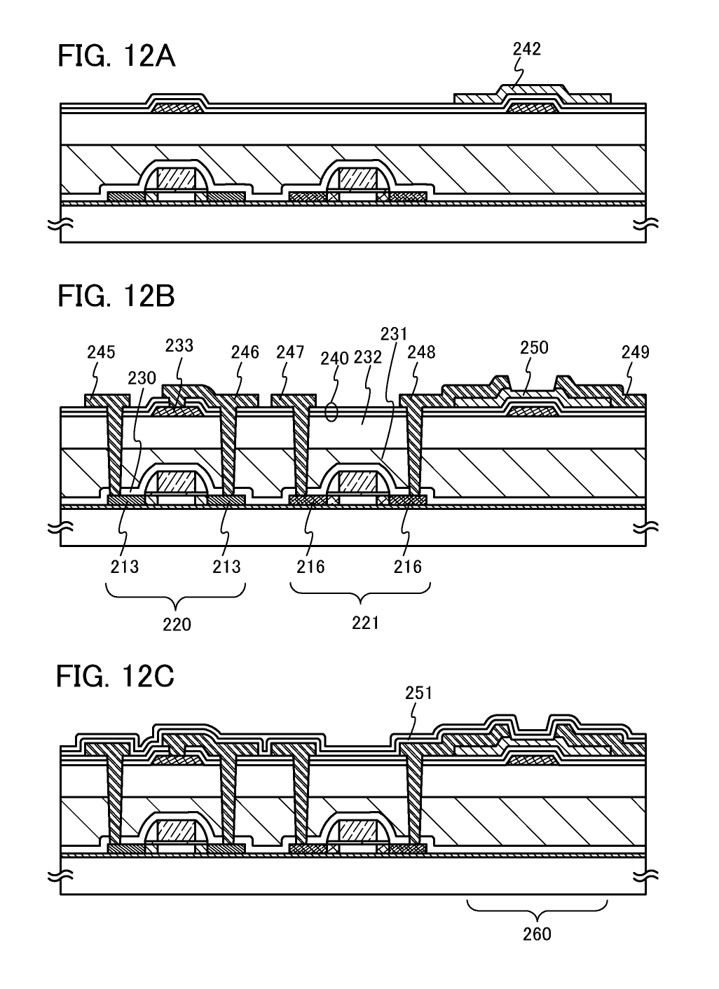

Next, heat treatment may be performed on the oxide semiconductor film 241 in a reduced atmosphere, an inert gas atmosphere such as a nitrogen atmosphere or a rare gas atmosphere, an oxygen gas atmosphere, or an ultra dry air atmosphere (in air whose moisture content is less than or equal to 20 ppm (dew point conversion, −55° C.), preferably, less than or equal to 1 ppm, more preferably, less than or equal to 10 ppb in the case where measurement is performed using a dew-point hygrometer of a cavity ring-down laser spectroscopy (CRDS) system). By performing the heat treatment on the oxide semiconductor film 241, an oxide semiconductor film 242 in which the amount of impurities such as hydrogen and water is reduced is formed as illustrated in FIG. 12A. In particular, the heat treatment is performed by rapid thermal anneal (RTA) treatment in an inert gas atmosphere (nitrogen, helium, neon, argon, or the like) at a temperature of higher than or equal to 300° C. and lower than or equal to 750° C. (or a temperature less than or equal to the strain point of the glass substrate) for approximately 1 minute to 10 minutes, preferably at 650° C. for approximately 3 minutes to 6 minutes. With an RTA method, dehydration or dehydrogenation can be performed in a short time; therefore, the treatment can be performed even at a temperature higher than the strain point of a glass substrate. Note that a timing of the heat treatment is not limited to after formation of the island-shaped oxide semiconductor film 241, and the heat treatment may be performed on the oxide semiconductor film before etching. In addition, the heat treatment may be performed plural times after the island-shaped oxide semiconductor film 241 is formed.

In this embodiment, heat treatment is performed for 6 minutes in a nitrogen atmosphere in the state where the substrate temperature reaches 600° C. Further, a heating method using an electric furnace, a rapid heating method such as a gas rapid thermal annealing (GRTA) method using a heated gas or a lamp rapid thermal annealing (LRTA) method using lamp light, or the like can be used for the heat treatment. For example, in the case of performing heat treatment using an electric furnace, the temperature rise characteristics is preferably set at higher than or equal to 0.1° C./min and lower than or equal to 20° C./min and the temperature drop characteristics is preferably set at higher than or equal to 0.1° C./min and lower than or equal to 15° C./min.

Note that in the heat treatment, it is preferable that moisture, hydrogen, and the like be not contained in nitrogen or a rare gas such as helium, neon, or argon. It is preferable that the purity of nitrogen or the rare gas such as helium, neon, or argon which is introduced into a heat treatment apparatus be set to be 6N (99.9999%) or higher, preferably 7N (99.99999%) or higher (that is, the impurity concentration is 1 ppm or lower, preferably 0.1 ppm or lower).

Next, the insulating film 230, the insulating film 231, the insulating film 232, and the gate insulating film 240 are partly etched, so that contact holes reaching the high-concentration impurity regions 213 included in the transistor 220, contact holes reaching the high-concentration impurity regions 216 included in the transistor 221, and a contact hole reaching the wiring 233 are formed. Then, a conductive film used for source and drain electrodes is formed over the oxide semiconductor film 242 by a sputtering method or a vacuum vaper deposition method. After that, the conductive film is patterned by etching or the like, so that conductive films 245 to 249 functioning as the source and drain electrodes are formed as illustrated in FIG. 12B.

In particular, the conductive film 245 and the conductive film 246 are connected to the pair of high-concentration impurity regions 213 included in the transistor 220. In addition, the conductive film 246 is also connected to the wiring 233. The conductive film 247 and the conductive film 248 are connected to the pair of high-concentration impurity regions 216 included in the transistor 221. In addition, besides the conductive film 249, the conductive film 248 is also connected to the oxide semiconductor film 242.

As the conductive films 245 to 249, for example, a material such as an element selected from aluminum, chromium, tantalum, titanium, manganese, magnesium, molybdenum, tungsten, zirconium, beryllium, and yttrium; an alloy including one or more of these elements as a component; or the like can be used. Note that in the case where heat treatment is performed after the formation of the conductive film, the conductive film preferably has heat resistance enough to withstand the heat treatment. In the case of performing heat treatment after the formation of the conductive film, the conductive film is formed using the low-resistant conductive material in combination with aluminum because aluminum alone has problems of low heat resistance, being easily corroded, and the like. As the low-resistant conductive material which is combined with aluminum, the following material is preferably used: an element selected from titanium, tantalum, tungsten, molybdenum, chromium, neodymium, or scandium; an alloy including one or more of these elements as a component; a nitride including any of these elements as a component; or the like.

The thickness of each of the conductive films 245 to 249 is 10 nm to 400 nm, preferably 100 nm to 200 nm. In this embodiment, the conductive film for the source and drain electrodes which is obtained by stacking a titanium film, a titanium nitride film, an aluminum film, and a titanium film in this order is processed (patterned) to a desired shape by etching, so that the conductive films 245 to 249 are formed.

The etching for forming the conductive films 245 to 249 may be either wet etching or dry etching. In the case where the conductive films 245 to 249 are formed by dry etching, a gas containing chlorine (Cl₂), boron chloride (BCl₃), or the like is preferably used. In the etching step, an exposed region of the oxide semiconductor film 241 is partly etched, whereby an island-shaped oxide semiconductor film 250 is formed. Therefore, the thickness of the region of the oxide semiconductor film 250 between the conductive film 248 and the conductive film 249 is reduced.

As illustrated in FIG. 12C, after formation of the conductive films 245 to 249, an insulating film 251 is formed to cover the conductive films 245 to 249 and the oxide semiconductor film 250. The insulating film 251 preferably includes impurities such as moisture, hydrogen, and oxygen as little as possible, and may be formed using an insulating film of a single layer or a plurality of insulating films stacked. A material having a high barrier property is preferably used for the insulating film 251. For example, as the insulating having a high barrier property, a silicon nitride film, a silicon nitride oxide film, an aluminum nitride film, an aluminum nitride oxide film, or the like can be used. In the case where a plurality of insulating films stacked is used, an insulating film having lower proportion of nitrogen, such as a silicon oxide film, a silicon oxynitride film is provided on the side closer to the oxide semiconductor film 250 than the insulating film having a high barrier property. An insulating film having a barrier property is formed to overlap with the conductive films 245 to 249 and the oxide semiconductor film 250 with the insulating film having lower proportion of nitrogen therebetween. By using the insulating film having a barrier property, impurities such as moisture and hydrogen can be prevented from entering the oxide semiconductor film 250, the gate insulating film 240, and an interface between the oxide semiconductor film 250 and another insulating film and the vicinity thereof. In addition, when the insulating film having lower proportion of nitrogen, such as a silicon oxide film or a silicon oxynitride film is formed in contact with the oxide semiconductor film 250, the insulating film formed using a material having a high barrier property can be prevented from being directly in contact with the oxide semiconductor film 250.

In this embodiment, the insulating film 251 having a structure in which a silicon nitride film with a thickness of 100 nm formed by a sputtering method is stacked over a silicon oxide film with a thickness of 200 nm formed by a sputtering method is formed. The substrate temperature in deposition may be higher than or equal to room temperature and lower than or equal to 300° C. and in this embodiment, is 100° C.

When the exposed region of the oxide semiconductor film 250 between the conductive film 248 and the conductive film 249 is provided in contact with the silicon oxide included in the insulating film 251, resistance of the region of the oxide semiconductor film 250 in contact with the insulating film 251 is increased, so that the oxide semiconductor film 250 including a channel formation region whose resistance is increased can be obtained.

Next, after the insulating film 251 is formed, heat treatment may be performed. The heat treatment is performed in an air atmosphere or an inert gas atmosphere (nitrogen, helium, neon, argon, or the like). The heat treatment is preferably performed at a temperature higher than or equal to 200° C. and lower than or equal to 400° C., for example, at a temperature higher than or equal to 250° C. and lower than or equal to 350° C. For example, the heat treatment is performed at 250° C. in a nitrogen atmosphere for one hour. Alternatively, in a similar manner to the heat treatment performed on the oxide semiconductor film 241, RTA treatment at a high temperature for short time may be performed. By the heat treatment, the oxide semiconductor film 250 is heated while being in contact with the silicon oxide included in the insulating film 251. Therefore, the resistance of the oxide semiconductor film 250 is further increased. Accordingly, electric characteristics of the transistors can be improved and variation in the electric characteristics thereof can be reduced. There is no particular limitation on the timing of the heat treatment as long as it is performed after the insulating film 251 is formed. When this heat treatment also serves as heat treatment in another step, for example, heat treatment in formation of a resin film or heat treatment for reducing resistance of a transparent conductive film, the number of steps can be prevented from increasing.

Through the above steps, a transistor 260 including the oxide semiconductor film 250 as an active layer can be manufactured.

Next, a back gate electrode may be formed in a portion overlapping with the oxide semiconductor film 250 in such a manner that a conductive film is formed over the insulating film 251 and then the conductive film is patterned. The back gate electrode can be formed using the same materials and the same structures as those of the gate electrode 234 and the conductive films 245 to 249.

The thickness of the back gate electrode is set to be 10 nm to 400 nm, preferably 100 nm to 200 nm For example, the back gate electrode may be formed in a such a manner that a conductive film in which a titanium film, an aluminum film, and a titanium film are stacked is formed, a resist mask is formed by a photolithography method, and unnecessary portions are removed by etching so that the conductive film is processed (patterned) to a desired shape.

In the case where the back gate electrode is formed, an insulating film is preferably formed to cover the back gate electrode. The insulating film is preferably formed using a material having a high barrier property which can prevent moisture, hydrogen, oxygen, and the like in an atmosphere from influencing characteristics of the transistor 260. For example, the insulating film having a high barrier property can be formed to have a single-layer structure or a stacked-layer structure including a silicon nitride film, a silicon nitride oxide film, an aluminum nitride film, an aluminum nitride oxide film, and/or the like by a plasma CVD method, a sputtering method, or the like. In order to obtain an effect of a barrier property, the insulating film is preferably formed to a thickness of 15 nm to 400 nm, for example.

Note that although the back gate electrode may formed to cover the whole oxide semiconductor film 250, the back gate electrode is not necessarily formed to cover the whole oxide semiconductor film 250 as long as it overlaps with at least part of the channel formation region included in the oxide semiconductor film 250.

Further, the back gate electrode may be electrically insulated and in a floating state, or may be in a state where the back gate electrode is supplied with a potential. In the case of the latter, the back gate electrode may be supplied with the same potential as the gate electrode 234, or may be supplied with a fixed potential such as a ground potential. The level of the potential supplied to the back gate electrode is controlled, whereby the threshold voltage of the transistor 260 can be controlled.

Note that it is possible to form a wiring connected to any of the conductive films 245 to 249 in such a manner that after a contact hole reaching any of the conductive films 245 to 249 is formed by partly etching the insulating film 251, a conductive film is formed over the insulating film 251, and then the conductive film is patterned.

Note that in this embodiment, after formation of the transistor including silicon, the transistor including an oxide semiconductor film is stacked; however, an embodiment of the present invention is not limited to this structure. The transistor including silicon and the transistor including an oxide semiconductor film may be formed over one insulating surface, or the transistor including silicon may be stacked after formation of the transistor including an oxide semiconductor film. Note that in the case where the transistor including silicon is stacked after formation of the transistor including an oxide semiconductor film, microcrystalline silicon or polycrystalline silicon is used as the silicon. This embodiment can be implemented in combination with any of the above embodiments.

### Embodiment 3

In this embodiment, a transistor including an oxide semiconductor film has a structure which is different from that of the transistor of Embodiment 2 is described.

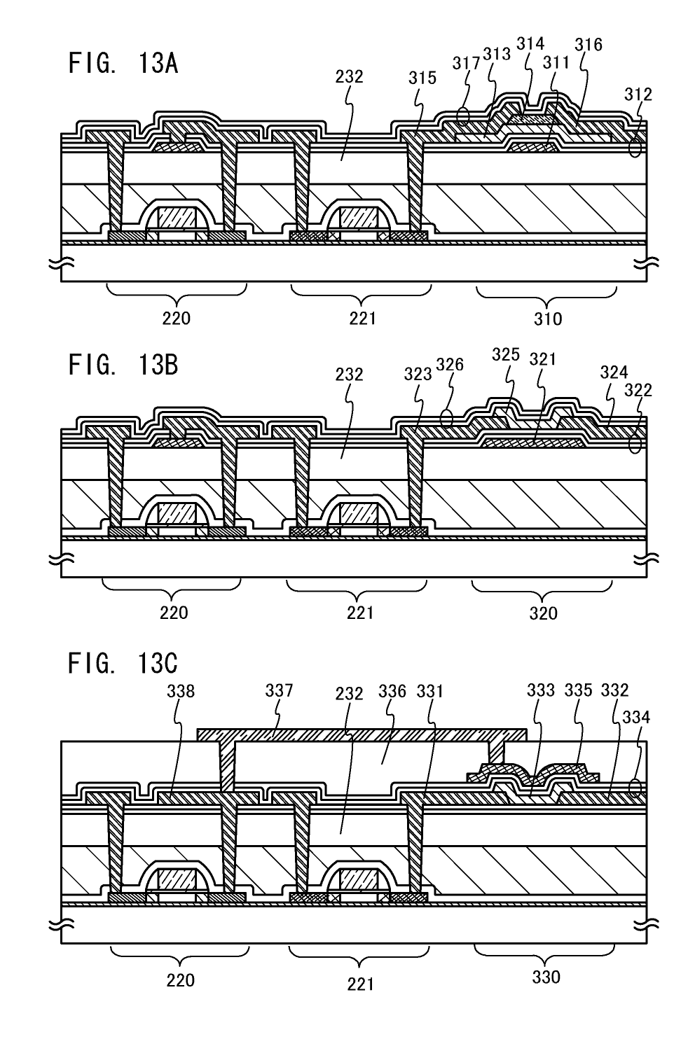

In a similar manner to Embodiment 2, a semiconductor device illustrated in FIG. 13A includes an n-channel transistor 220 and a p-channel transistor 221 each of which includes crystalline silicon. In addition, a bottom-gate transistor 310 which has a channel-protective structure and includes an oxide semiconductor film is formed over the n-channel transistor 220 and the p-channel transistor 221 in FIG. 13A.

The transistor 310 includes a gate electrode 311 provided over the insulating film 232, a gate insulating film 312 provided over the gate electrode 311, an oxide semiconductor film 313 which overlaps with the gate electrode 311 over the gate insulating film 312, a channel protective film 314 which is provided over the island-shaped oxide semiconductor film 313 to overlap with the gate electrode 311, and a conductive film 315 and a conductive film 316 which are provided over the oxide semiconductor film 313. The transistor 310 may include an insulating film 317 provided over the oxide semiconductor film 313, as its component.

The channel protective film 314 can prevent the portion of the oxide semiconductor film 313 which serves as a channel formation region later, from being damaged in a later step (for example, reduction in thickness due to plasma or an etchant in etching). Thus, reliability of the transistor can be improved.

An inorganic material containing oxygen (silicon oxide, silicon nitride oxide, silicon oxynitride, aluminum oxide, aluminum oxynitride, or the like) can be used for the channel protective film 314. The channel protective film 314 can be formed by a vapor deposition method such as a plasma CVD method or a thermal CVD method, or a sputtering method. After the deposition of the channel protective film 314, the shape thereof is processed by etching. Here, the channel protective film 314 is formed in such a manner that a silicon oxide film is formed by a sputtering method and processed by etching using a mask formed by photolithography.

When the channel protective film 314, which is an insulating film containing oxygen, is formed in contact with the island-shaped oxide semiconductor film 313 by a sputtering method, a PCVD method, or the like, at least a region of the island-shaped oxide semiconductor film 313 in contact with the channel protective film 314 is increased in resistance to be a high-resistance oxide semiconductor region. By the formation of the channel protective film 314, the oxide semiconductor film 313 can include the high-resistance oxide semiconductor region which is provided in the vicinity of the interface between the oxide semiconductor film 313 and channel protective film 314.

Note that the transistor 310 may further include a back gate electrode over the insulating film 317. The back gate electrode is formed so as to overlap with a channel formation region in the oxide semiconductor film 313. The back gate electrode may be electrically insulated and in a floating state, or may be in a state where the back gate electrode is supplied with a potential. In the case of the latter, the back gate electrode may be supplied with the same potential as the gate electrode 311, or may be supplied with a fixed potential such as a ground potential. The level of the potential supplied to the back gate electrode is controlled, whereby the threshold voltage of the transistor 310 can be controlled.

In a similar manner to Embodiment 2, a semiconductor device illustrated in FIG. 13B includes the n-channel transistor 220 and the p-channel transistor 221 each of which includes crystalline silicon. In addition, a bottom-contact transistor 320 including an oxide semiconductor film is formed over the n-channel transistor 220 and the p-channel transistor 221 in FIG. 13B.

The transistor 320 includes a gate electrode 321 provided over the insulating film 232, a gate insulating film 322 provided over the gate electrode 321, a conductive film 323 and a conductive film 324 provided over the gate insulating film 322, and an oxide semiconductor film 325 overlapping with the gate electrode 321. In addition, the transistor 320 may include an insulating film 326 provided over the oxide semiconductor film 325, as its component.

In addition, in the case of the bottom-contact transistor 320, the thicknesses of the conductive film 323 and the conductive film 324 are preferably smaller than those of the bottom-gate transistor described in Embodiment 2 in order to prevent disconnection of the oxide semiconductor film 325 formed later. Specifically, the thickness of each of the conductive film 323 and the conductive film 324 is 10 nm to 200 nm, preferably 50 nm to 75 nm.

Note that the transistor 320 may further include a back gate electrode over the insulating film 326. The back gate electrode is formed so as to overlap with a channel formation region in the oxide semiconductor film 325. The back gate electrode may be electrically insulated and in a floating state, or may be in a state where the back gate electrode is supplied with a potential. In the case of the latter, the back gate electrode may be supplied with the same potential as the gate electrode 321, or may be supplied with a fixed potential such as a ground potential. The level of the potential supplied to the back gate electrode is controlled, whereby the threshold voltage of the transistor 320 can be controlled.

In a similar manner to Embodiment 2, a semiconductor device illustrated in FIG. 13C includes the n-channel transistor 220 and the p-channel transistor 221 each of which includes crystalline silicon. In addition, a top-gate transistor 330 including an oxide semiconductor film is provided over the n-channel transistor 220 and the p-channel transistor 221 in FIG. 13C.

The transistor 330 includes a conductive film 331 and a conductive film 332 provided over the insulating film 232, an oxide semiconductor film 333 provided over the conductive film 331 and the conductive film 332, a gate insulating film 334 provided over the oxide semiconductor film 333, and a gate electrode 335 overlapping with the oxide semiconductor film 333 over the gate insulating film 334. In addition, the transistor 330 may include an insulating film 336 provided over the gate electrode 335, as its component.

In the case of the top-gate transistor 330, the thickness of each of the conductive film 331 and the conductive film 332 is preferably smaller than that of the bottom-gate transistor described in Embodiment 2 in order to prevent disconnection of the oxide semiconductor film 333 formed later. Specifically, the thickness of each of the conductive film 331 and the conductive film 332 is 10 nm to 200 nm, preferably 50 nm to 75 nm.

In addition, in the semiconductor device illustrated in FIG. 13C, a contact hole reaching the gate electrode 335 and a contact hole reaching the conductive film 338 functioning as the source electrode or the drain electrodes may be formed in the insulating film 336 and the gate insulating film 334 and then a wiring 337 connected to the gate electrode 335 and a conductive film 338 may be formed.

This embodiment can be implemented in combination with any of the above embodiments.

### Embodiment 4

In this embodiment, a structure of a semiconductor display device referred to as electronic paper or digital paper, which is a semiconductor display device relating to an embodiment of the present invention, is described.

A display element which can control grayscale by voltage application and has a memory property is used for electronic paper. Specifically, as the display element used for electronic paper, a display element such as a non-aqueous electrophoretic display element; a display element using a PDLC (polymer dispersed liquid crystal) method, in which liquid crystal droplets are dispersed in a high polymer material that is between two electrodes; a display element which includes chiral nematic liquid crystal or cholesteric liquid crystal between two electrodes; a display element which includes charged fine particles between two electrodes and employs a particle-moving method by which the charged fine particles are moved through fine particles by using an electric field; or the like can be used. Further, a non-aqueous electrophoretic display element may be a display element in which a dispersion liquid, in which charged fine particles are dispersed, is sandwiched between two electrodes; a display element in which a dispersion liquid in which charged fine particles are dispersed is included over two electrodes between which an insulating film is interposed; a display element in which twisting balls having hemispheres which are different colors which charge differently are dispersed in a solvent between two electrodes; a display element which includes microcapsules, in which a plurality of charged fine particles are dispersed in a solution, between two electrodes; or the like.

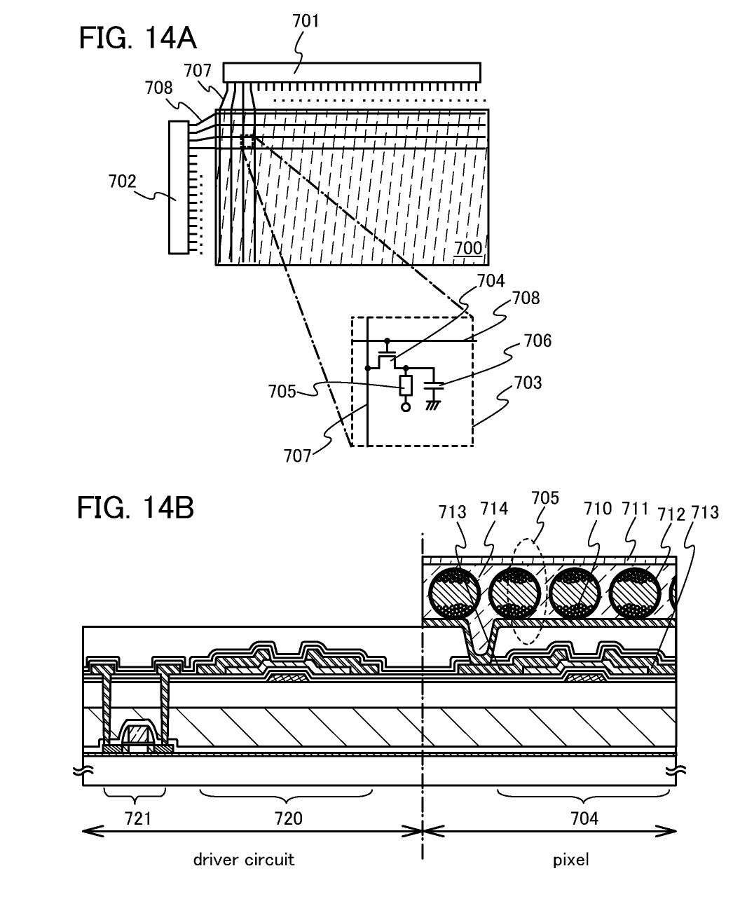

FIG. 14A illustrates a top view of a pixel portion 700, a signal line driver circuit 701, and a scan line driver circuit 702 of electronic paper.

The pixel portion 700 includes a plurality of pixels 703. Further, a plurality of signal lines 707 is led into the pixel portion 700 from the signal line driver circuit 701. A plurality of scan lines 708 is led into the pixel portion 700 from the signal line driver circuit 702.

The pixel 703 includes a transistor 704, a display element 705, and a storage capacitor 706. A gate electrode of the transistor 704 is connected to one of the scan lines 708. Further, one of a source electrode and a drain electrode of the transistor 704 is connected to one of the signal lines 707 and the other of the source electrode and the drain electrode of the transistor 704 is connected to a pixel electrode of the display element 705. Note that in FIG. 14A, the storage capacitor 706 is connected in parallel to the display element 705 such that a voltage applied between the pixel electrode and the counter electrode of the display element 705 is held; however, in the case where the memory property of the display element 705 is sufficiently high enough to maintain display, the storage capacitor 706 is not necessarily provided.

Note that in FIG. 14A, although an active-matrix pixel portion structure in which one transistor which serves as a switching element is provided in each pixel is described in this embodiment, electronic paper according to one embodiment of the present invention is not limited to this structure. A plurality of transistors may be provided in each pixel. Further, other than a transistor an, element such as a capacitor, a resistor, a coil, or the like may also be provided.

Using electronic paper of an electrophoretic system having microcapsules as an example, a cross-sectional view of a display element 705 provided in each of pixels 703 and a cross-sectional view of a semiconductor device used for a driver circuit such as the signal line driver circuit 701 or the scan line driver circuit 702 are illustrated in FIG. 14B.

In the pixel, the display element 705 includes a pixel electrode 710, a counter electrode 711, and microcapsules 712 to which voltage is applied by the pixel electrode 710 and the counter electrode 711. One of conductive films 713 serving as the source electrode and the drain electrode of a transistor 704 is connected to the pixel electrode 710.

In the transistor 704, an oxide semiconductor film is used as an active layer. Therefore, off current in the state where voltage between a gate electrode and a source electrode is approximately 0, that is, leakage current of the transistor 704 is much smaller than that of a transistor including silicon having crystallinity.

In the microcapsules 712, positively charged white pigment such as titanium oxide and negatively charged black pigment such as carbon black are sealed together with a dispersion medium such as oil. A voltage is applied between the pixel electrode and the counter electrode in accordance with the voltage of a video signal applied to the pixel electrode 710, and black pigment and white pigment are drawn to a positive electrode side and a negative electrode side, respectively. Therefore, the grayscale can be displayed.

Further, in FIG. 14B, the microcapsules 712 are fixed by light-transmitting resin 714 between the pixel electrode 710 and the counter electrode 711. However, the present invention is not limited to this structure. A space formed by the microcapsules 712, the pixel electrode 710, and the counter electrode 711 may be filled with gas such as inert gas or air. Note that in this case, the microcapsules 712 are preferably fixed to both or one of the pixel electrode 710 and the counter electrode 711 by an adhesive or the like.

Note that the number of the microcapsules 712 included in the display element 705 is not necessarily plural as in FIG. 14B. One display element 705 may include a plurality of microcapsules 712 or a plurality of display elements 705 may include one microcapsule 712. For example, two display elements 705 share one microcapsule 712, and positive voltage and negative voltage are applied to the pixel electrode 710 included in one of the display elements 705 and the pixel electrode 710 included in the other of the display elements 705, respectively. In this case, in the microcapsule 712 in a region overlapping with the pixel electrode 710 to which positive voltage is applied, black pigment is drawn to the pixel electrode 710 side and white pigment is drawn to the counter electrode 711 side. On the other hand, in the microcapsule 712 in a region overlapping with the pixel electrode 710 to which negative voltage is applied, white pigment is drawn to the pixel electrode 710 side and black pigment is drawn to the counter electrode 711 side.

In addition, in the driver circuit, a transistor 720 including an oxide semiconductor film as an active layer and a transistor 721 including silicon as an active layer are provided. As a switching element for controlling supply of a power supply voltage to a circuit including the transistor 721, the transistor 720 can be used.

In a non-operation period, when supply of the power supply voltage to the circuit is stopped by the switching element, dynamic standby power consumed in the circuit can be reduced. In addition, since the oxide semiconductor film is used as the active layer in the transistor 720, off current in a state where voltage between a gate electrode and a source electrode is approximately 0, that is, leakage current of the transistor 720 is much smaller than that of the transistor 721 including silicon having crystallinity. Therefore, when the transistor 720 is used as the switching element, static standby power depending on leakage current or the like which is generated in the switching element can be reduced. Accordingly, when supply of the power supply voltage to the non-operation circuit is stopped, both the static standby power and the dynamic standby power consumed in the non-operation circuit are reduced, so that the semiconductor device in which power consumption of the whole circuit can be reduced can be obtained.

In particular, the electric paper includes the display element having a high memory property as compared to other semiconductor display devices such as a liquid crystal display device or a light-emitting device; therefore, when display is performed, a period in which the operation of the driving circuit such as the signal line driver circuit 701 or the scan line driver circuit 702 can be stopped tends to be long. Therefore, by application of an embodiment of the present invention, standby power can be reduced more effectively as compared to other semiconductor display devices.

In addition, the transistor 721 including silicon having crystallinity has higher mobility and higher on current than the transistor 720 including an oxide semiconductor. Therefore, by forming the circuit with the use of the transistor 721, high integration of the integrated circuit including the circuit and high speed driving thereof can be achieved.

Next, the above electronic paper of the electrophoretic system is given as one example to describe a specific driving method of electronic paper.

Operation of the electronic paper can be separately described as the following periods: an initialization period, a writing period, and a holding period.

First, the grayscale levels of each of the pixels of a pixel portion are temporarily set to be equal in the initialization period before a display image is switched in order to initialize display elements. Initialization of the display elements prevents a residual image from remaining. Specifically, in an electrophoretic system, displayed grayscale level is adjusted by the microcapsule 712 included in the display element 705 such that the display of each pixel is white or black.

In this embodiment, operation of initialization in the case where after an initialization video signal for displaying black is input to a pixel, an initialization video signal for displaying white is input to a pixel will be described. For example, when the electronic paper of an electrophoretic system in which display of an image is performed to the counter electrode 711 side, voltage is applied to the display element 705 such that black pigment in the microcapsule 712 moves to the counter electrode 711 side and white pigment in the microcapsule 712 moves to the pixel electrode 710 side. Next, voltage is applied to the display element 705 such that white pigment in the microcapsule 712 moves to the counter electrode 711 side and black pigment in the microcapsule 712 moves to the pixel electrode 710 side.

Further, when an initialization video signal is input to the pixel only once, white pigment and black pigment in the microcapsule 712 do not finish moving completely depending on the grayscale level displayed before the initialization period, thus it is possible that difference between displayed grayscale levels of pixels occurs even after the initialization period ends. Therefore, it is preferable that negative voltage −Vp with respect to common voltage Vcom be applied to the pixel electrode 710 plural times so that black is displayed and positive voltage Vp with respect to the common voltage Vcom be applied to the pixel electrode 710 plural times so that white is displayed.

Note that when grayscale levels displayed before the initialization period differ depending on display elements of each of the pixels, the minimum number of times necessary for inputting an initialization video signal also varies. Accordingly, the number of times for inputting an initialization video signal may be changed between pixels in accordance with a grayscale level displayed before the initialization period. In this case, the common voltage Vcom is preferably input to a pixel to which the initialization video signal is not necessarily input.

Note that in order for the voltage Vp or the voltage −Vp which is an initialization video signal to be applied to the pixel electrode 710 plural times, the following operation sequence is performed plural times: the initialization video signal is input to pixels of a scan line in a period during which a pulse of a selection signal is supplied to the scan line. The voltage Vp or the voltage −Vp which is an initialization video signal is applied to the pixel electrode 710 plural times, whereby movement of white pigment and black pigment in the microcapsule 712 is completed in order to prevent difference of grayscale levels between pixels from occurring. Thus, initialization of a pixel of the pixel portion can be performed.

Note that in each pixel in the initialization period, the case where black is displayed after white as well as the case where white is displayed after black is acceptable. Alternatively, in each pixel in the initialization period, the case where black is displayed after white is displayed; and further, after that white is displayed is also acceptable.

Further, as for all of the pixels in the pixel portion, timing of starting the initialization period is not necessarily the same. For example, timing of starting the initialization period may be different for every pixels, or every pixels belonging to the same line, or the like.

Next in the writing period, a video signal having image data is input to the pixel.

In the case where an image is displayed on the entire pixel portion, in one frame period, a selection signal in which a pulse of voltage is shifted is sequentially input to all of the scan lines. Then, in one line period in which a pulse appears in a selection signal, a video signal having image data is input to all of the signal line.

White pigment and black pigment in the microcapsule 712 are moved to the pixel electrode 710 side and the counter electrode 711 in accordance with the voltage of the video signal applied to the pixel electrode 710, so that the display element 705 displays a grayscale.

Note that also in the writing period, the voltage of a video signal is preferably applied to the pixel electrode 710 plural times as in the initialization period. Accordingly, the following operation sequence is performed a plurality of times: the video signal is input to pixels of a scan line in a period during which a pulse of a selection signal is supplied to the scan line.

Next, in the holding period, a selection signal is not input to a scan line or a video signal is not input to a signal line after the common voltage Vcom is input to all of the pixels through signal lines. Accordingly, the positions of white pigment and black pigment in the microcapsule 712 included in the display element 705 is maintained unless positive or negative voltage is applied between the pixel electrode 710 and the common electrode 711, so that the grayscale level displayed on the display element 705 is held. Therefore, an image written in the writing period is maintained even in the holding period.

Note that a voltage which is necessary for change of gray scales of the display element used for the electric paper tends to be higher than that of a liquid crystal element used for a liquid crystal display device or a light-emitting element used for a light-emitting device, such as an organic light-emitting element. Therefore, a potential difference between a source electrode and a drain electrode of the pixel transistor 704 used as the switching element becomes large in the writing period. As a result, off current is increased and the potential of the pixel electrode 710 is changed, so that disturbance of display is likely to occur. However, as described above, in an embodiment of the present invention, the oxide semiconductor film is used as an active layer of the transistor 704. Therefore, off current in a state where voltage between a gate electrode and the source electrode is approximately 0, that is, leakage current of the transistor 704 is much smaller than the transistor including silicon having crystallinity. Consequently, in the writing period, even when the potential difference between the source electrode and the drain electrode of the transistor 704 becomes large, off current can be suppressed and generation of disturbance of display due to change of the potential of the pixel electrode 710 can be prevented.

In this embodiment, the electric paper is given as an example of a semiconductor device of an embodiment of the present invention. The semiconductor display device of an embodiment of the present invention includes the following in its category: a liquid crystal display device, a light-emitting device in which a light-emitting element typified by an organic light-emitting element (OLED) is provided for each pixel, a digital micromirror device (DMD), a plasma display panel (PDP), a field emission display (FED), and other semiconductor display devices which include a driving circuit including a semiconductor element.

For example, like a screen saver, in the case where display of images is temporally stopped while supply of a power supply voltage to a semiconductor display device is performed, standby power consumed can be reduced.

This embodiment can be implemented in combination with any of the above embodiments.

### Embodiment 5

In this example, a structure of a liquid crystal display device relating to an embodiment of the present invention is described.

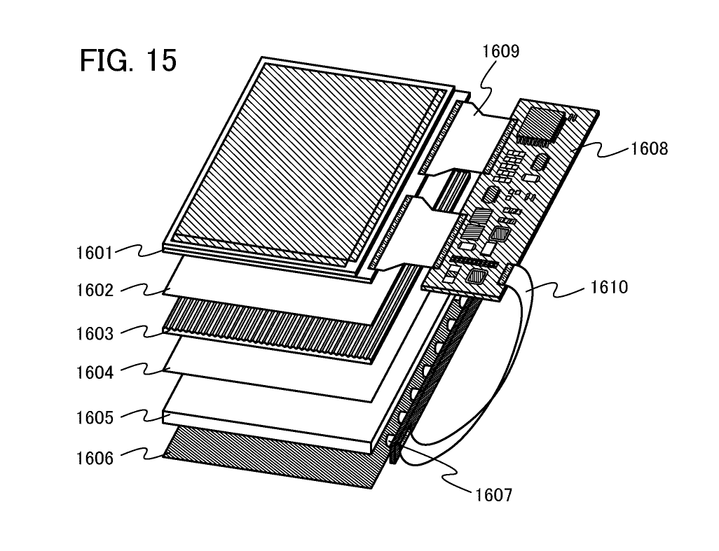

FIG. 15 illustrates an example of a perspective view illustrating a structure of the liquid crystal display device of an embodiment of the present invention. The liquid crystal display device illustrated in FIG. 15 includes a liquid crystal panel 1601 in which a liquid crystal element is formed between a pair of substrates, a first diffusing plate 1602, a prism sheet 1603, a second diffusing plate 1604, a light guide plate 1605, a reflection plate 1606, a light source 1607, and a circuit board 1608.

The liquid crystal panel 1601, the first diffusing plate 1602, the prism sheet 1603, the second diffusing plate 1604, the light guide plate 1605, and the reflection plate 1606 are stacked in this order. The light source 1607 is provided at an edge portion of the light guide plate 1605. The liquid crystal panel 1601 is uniformly irradiated with light from the light source 1607 which is diffused inside the light guide plate 1605, due to the first diffusing plate 1602, the prism sheet 1603, and the second diffusing plate 1604.

Although the first diffusing plate 1602 and the second diffusing plate 1604 are used in this embodiment, the number of diffusing plates is not limited thereto. The number of diffusing plates may be one, or may be three or more. It is acceptable as long as the diffusing plate is provided between the light guide plate 1605 and the liquid crystal panel 1601. Therefore, a diffusing plate may be provided only on the side closer to the liquid crystal panel 1601 than the prism sheet 1603, or may be provided only on the side closer to the light guide plate 1605 than the prism sheet 1603.

Further, the cross section of the prism sheet 1603 is not limited to a sawtooth-shape shown in FIG. 15. The prism sheet 1603 may have a shape with which light from the light guide plate 1605 can be concentrated on the liquid crystal panel 1601 side.

The circuit board 1608 is provided with a circuit which generates various kinds of signals input to the liquid crystal panel 1601, a circuit which processes the signals, or the like. In FIG. 15, the circuit board 1608 and the liquid crystal panel 1601 are connected to each other through an flexible printed circuit (FPC) 1609. Note that the circuit may be connected to the liquid crystal panel 1601 by using a chip-on-glass (COG) method, or part of the circuit may be connected to the FPC 1609 by using a chip-on-film (COF) method.

FIG. 15 illustrates an example in which the circuit board 1608 is provided with a controlling circuit which controls driving of the light source 1607 and the controlling circuit and the light source 1607 are connected to each other via the FPC 1610. Note that the above-described controlling circuits may be formed over the liquid crystal panel 1601. In that case, the liquid crystal panel 1601 and the light source 1607 are connected to each other through an FPC or the like.

Note that although FIG. 15 illustrates an edge-light type light source where the light source 1607 is provided on the edge of the liquid crystal panel 1601, a direct type light source where the light source 1607 is provided directly below the liquid crystal panel 1601 may be used. The liquid crystal display device according to an embodiment of the present invention may be a transmissive-type liquid crystal display device, a semi-transmissive type liquid crystal display device, or a reflective type liquid crystal display device.

The liquid crystal display device can include TN (twisted nematic) liquid crystals, VA (vertical alignment) liquid crystals, OCB (optically compensated birefringence) liquid crystals, IPS (in-plane switching) liquid crystals, or MVA (multi-domain vertical alignment) liquid crystals.

Alternatively, liquid crystal exhibiting a blue phase for which an alignment film is unnecessary may be used. A blue phase is one of liquid crystal phases, which is generated just before a cholesteric phase changes into an isotropic phase while temperature of cholesteric liquid crystal is increased. Since the blue phase is only generated within a narrow range of temperature, a chiral agent or an ultraviolet curable resin is added so that the temperature range is improved. The liquid crystal composition which includes a liquid crystal showing a blue phase and a chiral agent or an ultraviolet curable resin is preferable because it has a small response time of 10 μsec to 100 μsec, has optical isotropy, which makes the alignment process unneeded, and has a small viewing angle dependence.

This embodiment can be implemented in combination with any of the above embodiments.

### EXAMPLE 1

By using a semiconductor device relating to an embodiment of the present invention, an electronic appliance in which increase of power consumption can be prevented and which has high functions can be provided. In particular, the case of a portable electronic appliance to which electric power cannot be easily supplied constantly, continuous use time becomes longer by adding the semiconductor device relating to an embodiment of the present invention as a component, which is an advantage.

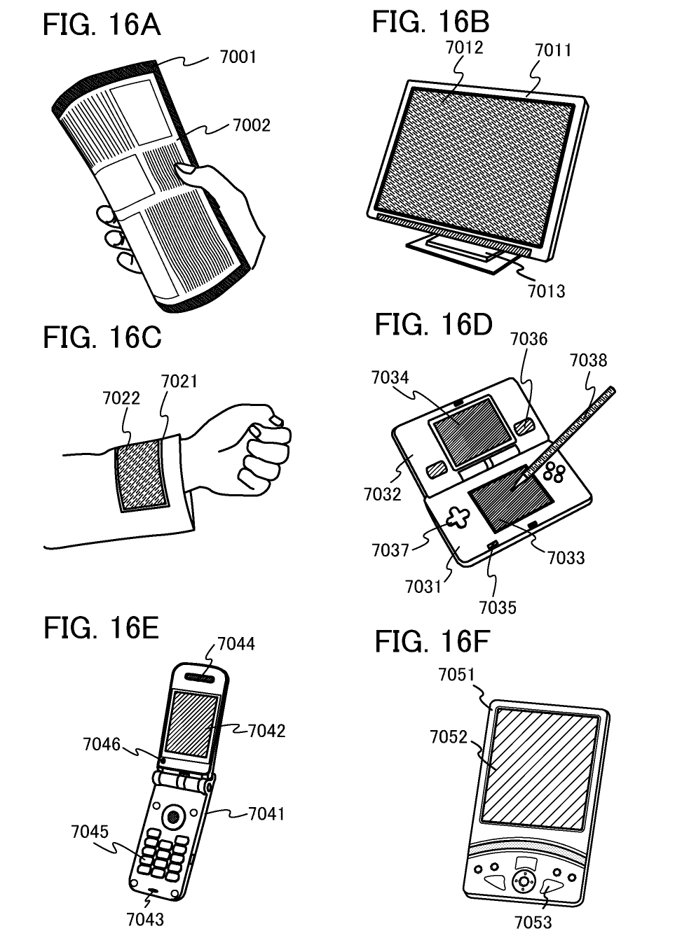

The semiconductor device according to one embodiment of the present invention can be used for display devices, laptops, or image reproducing devices provided with recording media (typically, devices which reproduce the content of recording media and have displays for displaying the reproduced images such as digital versatile discs (DVDs)). Other than the above, as an electronic appliance which can use the semiconductor device according to one embodiment of the present invention, mobile phones, portable game machines, portable information terminals, e-book readers, video cameras, digital still cameras, goggle-type displays (head mounted displays), navigation systems, audio reproducing devices (e.g., car audio systems and digital audio players), copiers, facsimiles, printers, multifunction printers, automated teller machines (ATM), vending machines, and the like can be given. Specific examples of these electronic appliances are illustrated in FIGS. 16A to 16F.

FIG. 16A illustrates an e-book reader including a housing 7001, a display portion 7002, and the like. The semiconductor display device relating to one embodiment of the present invention can be used for the display portion 7002. By including the semiconductor display device according to one embodiment of the present invention in the display portion 7002, an e-book reader with low power consumption and high functions can be provided. In addition, the semiconductor device relating to an embodiment of the present invention can be used for an integrated circuit which controls driving of the e-book reader. By using the semiconductor device relating to an embodiment of the present invention for the integrated circuit which controls driving of the e-book reader, the e-book reader with low power consumption and high functions can be provided. Moreover, with the use of a flexible substrate, a semiconductor device or a semiconductor display device can have flexibility. Thus, a flexible, lightweight, and useful e-book reader can be provided.

FIG. 16B illustrates a display device including a housing 7011, a display portion 7012, a supporting base 7013, and the like. The semiconductor display device relating to an embodiment of the present invention can be used for the display portion 7012. By using the semiconductor display device according to an embodiment of the present invention for the display portion 7012, a display device with low power consumption and high functions can be provided. The semiconductor device relating to an embodiment of the present invention can be used for an integrated circuit which controls driving of the display device. By using the semiconductor device relating to an embodiment of the present invention for the integrated circuit which controls driving of the display device, the display device with low power consumption and high functions can be provided. Note that a display device includes all display devices for displaying information, such as display devices for personal computers, for receiving television broadcast, and for displaying advertisement, in its category.

FIG. 16C illustrates a display device including a housing 7021, a display portion 7022, and the like. The semiconductor display device relating to an embodiment of the present invention can be used for the display portion 7022. By including the semiconductor display device relating to an embodiment of the present invention in the display portion 7022, a display device with low power consumption and high functions can be provided. The semiconductor device relating to an embodiment of the present invention can be used for an integrated circuit which controls driving of the display device. By using the semiconductor device relating to an embodiment of the present invention for the integrated circuit which controls driving of the display device, the display device with low power consumption and high functions can be provided. Moreover, with the use of a flexible substrate, a semiconductor device or a semiconductor display device can have flexibility. Thus, a flexible, lightweight, and useful display device can be provided. Accordingly, as illustrated in FIG. 16C, the display device can be used while being fixed to fabric or the like, and an application range of the semiconductor display device is dramatically widened.

FIG. 16D illustrates a portable game machine including a housing 7031, a housing 7032, a display portion 7033, a display portion 7034, a microphone 7035, speakers 7036, an operation key 7037, a stylus 7038, and the like. The semiconductor display device relating to an embodiment of the present invention can be used for the display portion 7033 and the display portion 7034. By including the semiconductor display device relating to an embodiment of the present invention in the display portion 7033 and the display portion 7034, a portable game machine with low power consumption and high functions can be provided. The semiconductor device relating to an embodiment of the present invention can be used for an integrated circuit which controls driving of the portable game machine. By using the semiconductor device relating to an embodiment of the present invention for the integrated circuit which controls driving of the portable game machine, the portable game machine with low power consumption and high functions can be provided. Note that the portable game machine illustrated in FIG. 16D has the two display portions 7033 and 7034. However, the number of display portions included in a portable game machine is not limited thereto.

FIG. 16E illustrates a mobile phone including a housing 7041, a display portion 7042, an audio-input portion 7043, an audio-output portion 7044, operation keys 7045, a light-receiving portion 7046, and the like. Light received in the light-receiving portion 7046 is converted into electrical signals, whereby external images can be loaded.

The semiconductor device relating to an embodiment of the present invention can be used for the display portion 7042. By including the semiconductor display device relating to an embodiment of the present invention in the display portion 7042, a mobile phone with low power consumption and high functions can be provided. The semiconductor device relating to an embodiment of the present invention can be used for an integrated circuit which controls driving of the mobile phone. By using the semiconductor device relating to an embodiment of the present invention for the integrated circuit which controls driving of the mobile phone, the mobile phone with low power consumption and high functions can be provided.

FIG. 16F is a portable information terminal which includes a housing 7051, a display portion 7052, an operation key 7053, and the like. In the portable information terminal illustrated in FIG. 16F, a modem may be incorporated in the housing 7051. The semiconductor display device relating to an embodiment of the present invention can be used for the display portion 7052. By using the semiconductor display device relating to an embodiment of the present invention for the display portion 7052, the portable information terminal with low power consumption and high functions can be provided. In addition, the semiconductor device relating to an embodiment of the present invention can be used for an integrated circuit for controlling driving of the portable information terminal By using the semiconductor device relating to an embodiment of the present invention for the integrated circuit which controls driving of the portable information terminal, the portable information terminal with low power consumption and high functions can be provided.

This embodiment can be implemented in combination with any of the above embodiments.

This application is based on Japanese Patent Application serial no. 2009-250665 filed with Japan Patent Office on Oct. 30, 2009, the entire contents of which are hereby incorporated by reference.

1. A semiconductor device comprising:
a circuit including a first transistor; and
a second transistor configured to control supply of a power supply voltage to the circuit,
wherein a channel formation region of the first transistor includes silicon having crystallinity, and
wherein a channel formation region of the second transistor includes an oxide semiconductor.

2. The semiconductor device according to claim 1, wherein the silicon having crystallinity is microcrystalline silicon, polycrystalline silicon, or single crystal silicon.

3. The semiconductor device according to claim 1, wherein the oxide semiconductor includes indium, gallium, and zinc.

4. The semiconductor device according to claim 1,
wherein the channel formation region of the first transistor is formed in a first semiconductor film,
wherein the channel formation region of the second transistor is formed in a second semiconductor film, and
wherein the first semiconductor film and the second semiconductor film are formed on different insulating surfaces.

5. A semiconductor device comprising:
a circuit including a first transistor;
a second transistor configured to control supply of a power supply voltage to the circuit; and
a control circuit including a third transistor and configured to control supply of a clock signal to the circuit,
wherein a channel formation region of the first transistor includes silicon having crystallinity, and
wherein each of a channel formation region of the second transistor and a channel formation region of the third transistor include an oxide semiconductor.

6. The semiconductor device according to claim 5, wherein the silicon having crystallinity is microcrystalline silicon, polycrystalline silicon, or single crystal silicon.

7. The semiconductor device according to claim 5, wherein the oxide semiconductor includes indium, gallium, and zinc.

8. The semiconductor device according to claim 5,
wherein the channel formation region of the first transistor is formed in a first semiconductor film,
wherein the channel formation region of the second transistor is formed in a second semiconductor film, and
wherein the first semiconductor film and the second semiconductor film are formed on different insulating surfaces.
